(19) United States
(12) Patent Application Publication
(10) Pub. No.: US 2009/0103376 A1
(43) Pub. Date: Apr. 23, 2009

(54) SEMICONDUCTOR MEMORY DEVICE

(75) Inventor: Kazushige KANDA, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/252,724

(22) Filed: Oct. 16, 2008

(30) Foreign Application Priority Data
Oct. 17, 2007 (JP) 2007-269795

(51) Int. Cl. G11C 7/00; G11C 29/56; G11C 7/16; G11C 7/18

(52) U.S. Cl. 365/189.05; 365/201; 365/200

(57) ABSTRACT

A semiconductor memory device related to an embodiment of the present invention includes a memory cell array including a plurality of memory cells, a first interface part having a predetermined number of pins, a second interface part having a smaller number of the pins than the first interface part, a data pattern latch part which stores an externally input data pattern, a comparison part which compares the data pattern input or preliminarily set from the data pattern latch part with data which is read from the memory cell array, and a comparison result output part arranged in the second interface part, and which outputs a comparison result of the comparison part.

### CROSS REFERENCE TO RELATED APPLICATION

This application is based upon and claims the benefit of priority from the prior Japanese Patent Application No. 2007-269795, filed on Oct. 17, 2007, the entire contents of which are incorporated herein by reference.

### BACKGROUND OF THE INVENTION

1. Field of the Invention

The present invention relates to a semiconductor memory device and in particular a semiconductor memory device arranged with an interface for testing.

2. Description of the Related Art

In the Japanese Laid Open Patent 2001-184899, an interface circuit for testing a memory mounted with a logic circuit is disclosed arranged with a control circuit for controlling programming and reading of data of a first in first out circuit responsive to an operation mode instruction signal which shows the input and output of data.

Furthermore, the above stated interface circuit only controls the programming and reading of test data to a first in first out circuit in response to an operation mode instruction signal which shows the input and output of data and does not disclose technology for storing the data for testing itself in an interface circuit and performing a test operation.

### BRIEF SUMMARY OF THE INVENTION

A semiconductor memory device related to an embodiment of the present invention includes a memory cell array including a plurality of memory cells, a first interface part having a predetermined number of pins, a second interface part having a smaller number of the pins than the first interface part, a data pattern latch part which stores an externally input or preliminarily set data pattern, a comparison part which compares the data pattern input from the data pattern latch part with data which is read from the memory cell array, and a comparison result output part arranged in the second interface part, and which outputs a comparison result of the comparison part.

### BRIEF DESCRIPTION OF THE DRAWINGS

FIG. 1 is a diagram which shows an outline construction of a test system for a semiconductor memory device related to embodiment of the present invention.

FIG. 2 is a block diagram which shows the main construction within a NAND type flash memory chip related to an embodiment of the present invention.

FIG. 3 is a diagram which shows a construction related to inputs and outputs within a NAND type flash memory chip related to an embodiment of the present invention.

FIG. 4 is a diagram which shows an example of an input waveform of each signal input to a NAND type flash memory chip related to an embodiment of the present invention.

FIG. 5 is a diagram which shows an example of a test board which connects a NAND type flash memory chip related to an embodiment of the present invention.

FIG. 6 is a diagram which shows a construction related to inputs and outputs within a NAND type flash memory chip related to a first embodiment of the present invention.

FIG. 7 is a diagram which shows an example of a test board which connects a NAND type flash memory chip related to a first embodiment of the present invention.

FIG. 8A is a diagram which shows an example of a data format when inputting a data code related to a first embodiment of the present invention.

FIG. 8B is a diagram which shows an example of a data format when outputting a data code related to a first embodiment of the present invention.

FIG. 9A is a diagram which shows an example of a waveform when inputting a command 00h related to a first embodiment of the present invention.

FIG. 9B is a diagram which shows and example of a waveform when outputting data related to a first embodiment of the present invention.

FIG. 10 is a diagram which shows a circuit construction of a data input/output part within a NAND type flash memory chip related to a first embodiment of the present invention.

FIG. 11 is a diagram which shows a circuit construction of a data input/output part within a NAND type flash memory chip related to a second embodiment of the present invention.

FIG. 12A is a diagram which shows a waveform of a signal which is input to a test pad related to a second embodiment of the present invention.

FIG. 12B is a diagram which shows a waveform of a signal related to a test operation of a first embodiment of the present invention.

FIG. 12C is a diagram which shows a waveform of a signal related to a test operation of a second embodiment of the present invention.

FIG. 13 is a diagram which shows an example of a comparison process and a comparison result of 8 bit data related to a second embodiment of the present invention.

FIG. 14 is a diagram which shows a circuit construction of a data input/output part within a NAND type flash memory chip related to a third embodiment of the present invention.

FIG. 15 is a diagram which shows an example of a comparison process and a comparison result of 8 bit data related to a third embodiment of the present invention.

FIG. 16 is a diagram which shows a circuit construction of a data input/output part within a NAND type flash memory chip related to a fourth embodiment of the present invention.

FIG. 17 is a flowchart which shows an example of a test operation performed within a NAND type flash memory chip related to a fourth embodiment of the present invention.

FIG. 18 is a diagram which shows an output example of a comparison process and a comparison result of 8 bit data related to a fourth embodiment of the present invention.

FIG. 19 is a flowchart which shows another example of a test operation performed within a NAND type flash memory chip related to a fourth embodiment of the present invention.

FIG. 20 is a diagram which shows another output example of a comparison process and a comparison result of 8 bit data related to a fourth embodiment of the present invention.

FIG. 21 is a diagram which shows a circuit construction of a data input/output part within a NAND type flash memory chip related to a fifth embodiment of the present invention.

FIG. 22 is a flowchart which shows an example of a test operation performed within a NAND type flash memory chip related to a fifth embodiment of the present invention.

FIG. 23 is a diagram which shows an output example of a comparison process and a comparison result of 8 bit data related to a fifth embodiment of the present invention.

FIG. 24 is a diagram which shows a circuit construction of a data input/output part within a NAND type flash memory chip related to a sixth embodiment of the present invention.

FIG. 25 is a flowchart which shows an example of a test operation performed within a NAND type flash memory chip related to a sixth embodiment of the present invention.

FIG. 26 is a diagram which shows an output example of a comparison process and a comparison result of 8 bit data related to a sixth embodiment of the present invention.

### DETAILED DESCRIPTION OF THE INVENTION

### Outline of a Semiconductor Memory Device Test

First, an outline of a semiconductor memory device test will be explained. A NAND type flash memory will be explained as an example of the semiconductor memory device.

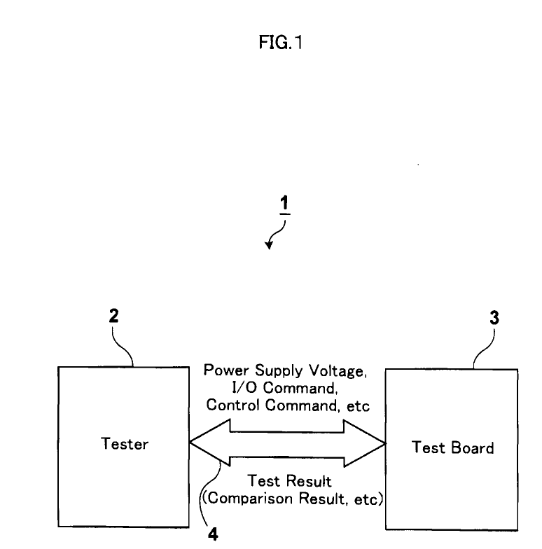

FIG. 1 is a diagram which shows an outline construction of a test system 1 which tests a NAND type flash memory. The test system 1 includes a tester 2 and a test board 3. The tester 2 is equipment for performing an operation test before shipment of a plurality of NAND type flash memory chips (not shown in the diagram) which are connected to the test board 3. The tester 2 and the test board 3 are connected by a cable 4 for sending and receiving a variety of signals for testing (e.g. power supply voltage, I/O command, control command, test data and reply signal etc).

The tester 2 stores a test program based on the specifications of the NAND type flash memory chip, supplies the variety of signals (e.g. power supply voltage, I/O command, control command and test data etc) to the plurality of NAND type flash memory chips on the test board 3 based on this test program and performs an operation test (programming, reading, erasure etc). Then, the tester 2 receives a reply signal of an operation test result (for example, a comparison result of read data) from each NAND type flash memory chip and indicates whether each NAND type flash memory chip is normal or defective.

The test board 3 is arranged with a plurality of pins (not shown in the diagram) for connecting the plurality of NAND type flash memory chips which are detachable. These pins are input with a variety of signals (e.g. power supply voltage, I/O command, control command and test data etc) which are supplied from the tester 2 via the above stated cable 4 and reply signals are output from each NAND type flash memory chip.

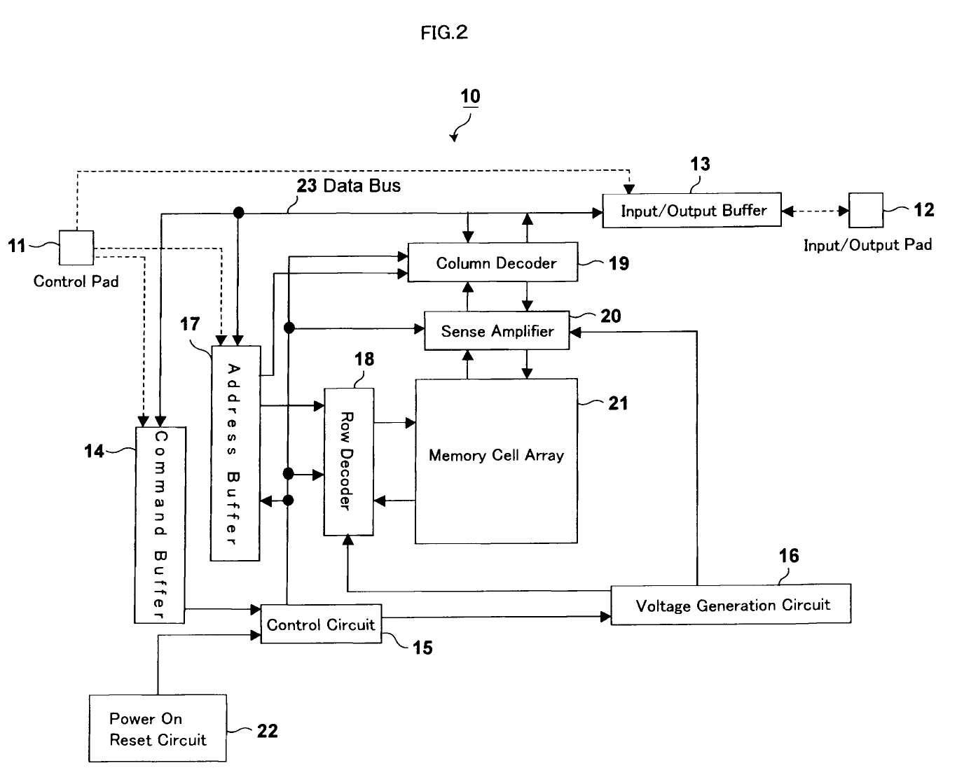

FIG. 2 is a block diagram which shows the main structure within a NAND type flash memory chip 10 connected to the above stated test board 3. The NAND type flash memory chip 10 is arranged with a control pad 11, an input/output pad 12, an input/output buffer 13, a command buffer 14, a control circuit 15, a voltage generation circuit 16, an address buffer 17, a row decoder 18, a column decoder 19, a sense amplifier 20 and a power on reset circuit 22. In the diagram the input/output buffer 13, command buffer 14, address buffer 17 and the column decoder 19 are connected with each other via a data bus 23.

The control pad 11 is a pad for receiving various control commands from external host equipment or the above stated tester 2. The input/output pad 12 is a pad for the input and output of data in units of 8 bits (herein referred to as 8 bit data) and is comprised from a plurality of I/O pads.

The input/output buffer 13 retains various control commands which are input from the control pad 11, data which is input from the input/output pad 12 or data which is input from the column decoder 19, inputs the retained control commands or data according to an operation within the NAND type flash memory chip 10 and outputs the retained data according to an operation of an external equipment or the above stated tester 2.

The command buffer 14 retains various control commands which are input from the control pad 11 and outputs these retained control commands to the control circuit 15. In addition, the command buffer 14 retains data which is input from the input/output buffer 13 and outputs the retained data to the control circuit 15.

The control circuit 15 performs sequential control operations such as data read, data program and data erasure based on various control commands which are input from the command buffer 14 according to an operation mode. In addition, the control circuit 15 outputs a control signal for generating a voltage necessary for various operation modes to the voltage generation circuit 16. Furthermore, the control circuit 15 resets each part within the NAND type flash memory chip 10 based on a power on reset command input from the power on reset circuit 22.

The voltage generation circuit 16 generates various voltages Vpp (programming voltage, verify voltage, programming bus voltage, read voltage etc) according to an operation mode and supplies these voltages to the row decoder 18 and the sense amplifier 20. The voltage generation circuit 16 is controlled by the control circuit 15.

The address buffer 17 stores address data input from the input/output buffer 13, outputs a row address to the row decoder 18 and outputs a column address to the column decoder 19.

The row decoder 18 selects a word line of the memory cell array 21 based on a row address input from the address buffer 17 and drives the selected word line.

The column decoder 19 connects the sense amplifier 20 with a data bus based on a column address input from the address buffer 17, inputs programming data to a latch circuit of the sense amplifier 20 and selects a column address which outputs read data from the latch circuit of the sense amplifier 20.

At the time of data input, the sense amplifier 20 programs data which is input from the input/output buffer 13 to nonvolatile memory cells within the memory cell array 21 which are selected by the row decoder 18 and the column decoder 19. In addition, at the time of data input, the sense amplifier 20 reads the data which is stored in the nonvolatile memory cells (not shown in the diagram) within memory cell array 21 which are selected by the row decoder 18 and the column decoder 19 and outputs the data to the input/output buffer 13.

The memory cell array 21 is comprised by arranging a plurality of NAND cell units (not shown in the diagram). Each NAND cell unit includes a plurality of electrically reprogrammable nonvolatile memory cells and a selection gate transistor for connecting both ends of the nonvolatile memory cells to a bit line and a source line respectively. Control gates of the nonvolatile memory cells are each respectively connected to different word lines. Gates of the selection gate transistors are connected to selection gates which run parallel to the word lines. A group of NAND cell units which share a word line is comprised of a memory block which is the unit of data erasure. A plurality of these memory blocks is included within the memory cell array 21.

The power on reset circuit 22 outputs a power on reset command to the control circuit 15 when a power supply from external host equipment or the above stated tester 2 is switched on.

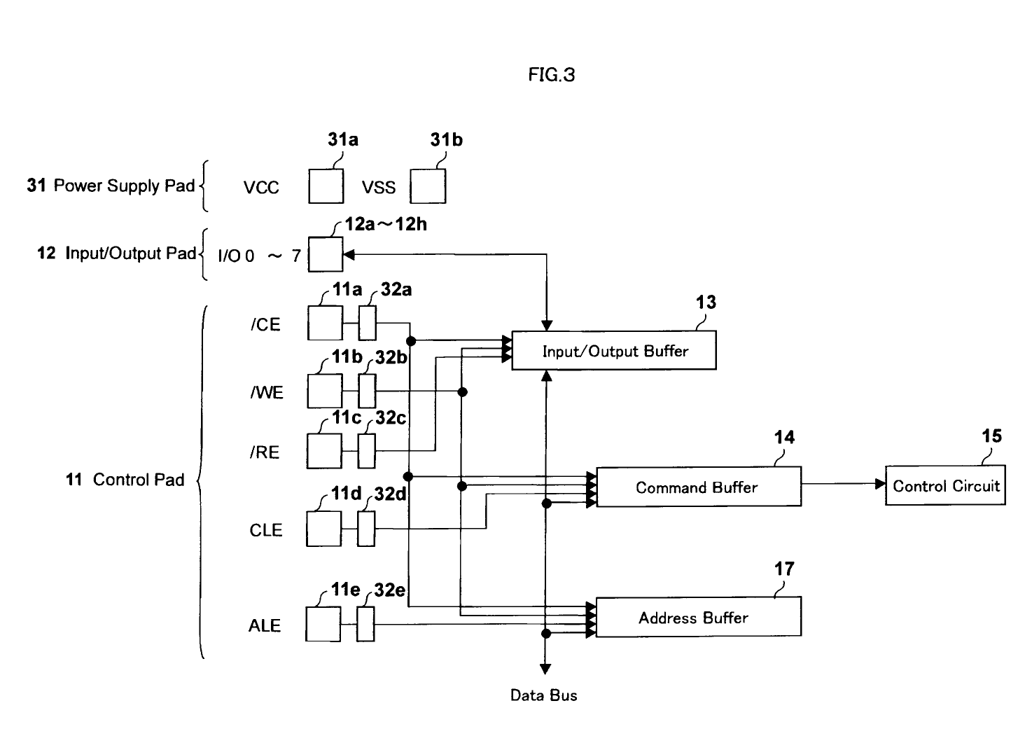

Next, the construction related to inputs and outputs within the NAND type flash memory chip 10 shown in FIG. 2 will be explained while referring to FIG. 3.

The control pad 11 includes pads 11a to 11e which respectively input a chip enable/CE, a write enable/WE, a read enable/RE, a command latch enable/CLE and address latch enable/ALE as control commands. In addition, input buffers 32a to 32e are connected between the input/output buffer 13, the command buffer 14, the address buffer 17 and the pads 11a to 11e. The input/output pad 12 includes I/O 0 to I/O 7 pads 12a to 12h which input and output data in units of 8 bits. The power supply pad 31 includes a pad 31a which inputs a power supply voltage VCC and a pad 31b which inputs a power supply voltage VSS.

Furthermore, in FIG. 3 a case where data in units of 8 bits is input and output is shown. However, data in units of 16 bits may also be input and output. A test mode in which data in units of 8 bits is input and output is called an [x8 mode] in the embodiments below. Chip enable/CE is a command for controlling activation and non-activation of the NAND type flash memory chip 10. When chip enable/CE is shown as non-activated (a “Hi” state), no other control command is input. Write enable/WE is used as a clock signal for setting an operation timing when data is input (when data is programmed) to the NAND flash memory chip 10. Read enable/RE is used as a clock signal for setting operation timing when data is output (when data is read) from the NAND type flash memory chip 10. Command latch enable/CLE is a signal which controls the import of control commands to the NAND type flash memory 10. When the command latch enable/CLE is a “Hi” state, input data which is input from an IO pin is recognized as a control command and imported to the NAND type flash memory chip 10. Address latch enable/ALE is a signal which controls the import of address data to the NAND type flash memory chip 10. When the address latch enable/ALE is a “Hi” state, input data which is input from an I/O pin is recognized as address data and imported to the NAND type flash memory chip 10.

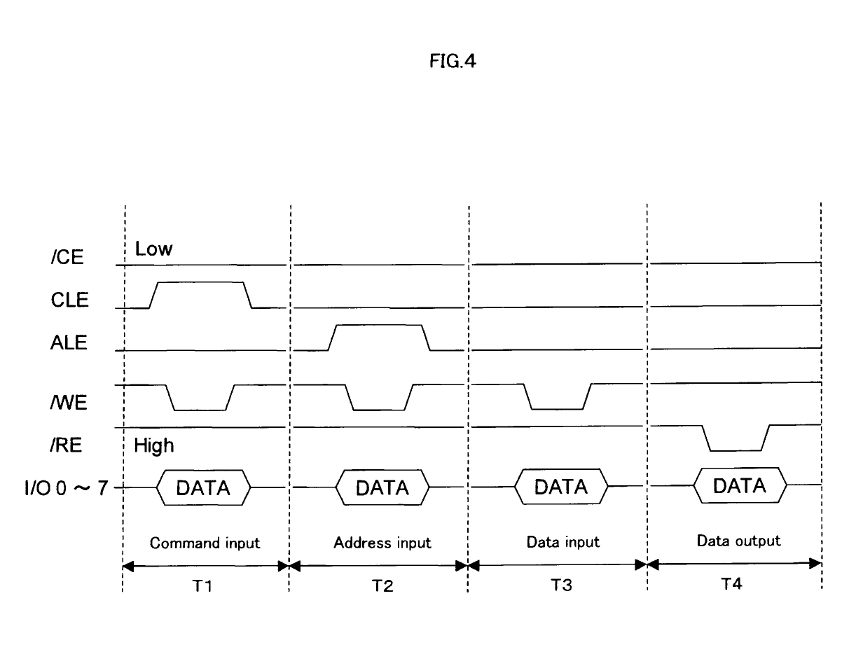

FIG. 4 is a diagram which shows an example of each input waveform of a control command which is input to the control pad 11 and a data command which is input to the input/output pad 12. An example of a chip enable/CE input waveform, a command latch enable/CLE input waveform, an address latch enable/ALE input waveform, a write enable/WE input waveform, a read enable/RE input waveform and each input waveform of data which is input to I/O 0 to I/O 7 pads 12a to 12h, are shown in FIG. 4.

During the command input time period T1 shown in FIG. 4, when chip enable/CE is a “Low” state, command latch enable/CLE is a “High” state and data is input to an I/O pin, if write enable/WE (“Low”) is input, the data of the 10 pin is recognized as command data and imported to the NAND type flash memory chip 10.

Next, during the address input time period T2 shown in FIG. 4, when chip enable/CE is a “Low” state, address latch enable/CLE is a “High” state and data is input to an IO pin, if write enable/WE (“Low”) is input, the data of the IO pin is recognized as address data and imported to the NAND type flash memory chip 10.

Next, during the data input time period T3 shown in FIG. 4, when chip enable/CE is a “Low” state, command latch enable/CLE and address latch enable/ALE are a “Low” state and data is input to I/O 0 to I/O 7 pads 12a to 12h, if write enable/WE (“Low”) is input, data is imported to the NAND type flash memory chip 10. The latch circuit to which the inputted data is imported is controlled by an operation mode of a command which is input before the data is input.

In addition, during the data input period T4 shown in FIG. 4, when chip enable/CE is a “Low” state and write enable/WE is a “Low” state, if read enable/RE (“Low”) is input, data is output from the NAND type flash memory chip 10. Similar to data input, this state is controlled by an operation mode of a command before data is input.

As stated above, command input, address input, data input and data output are carried out using a total of fifteen pads comprising two power supply pads 31, eight input/output pads 12 and five control pads 11 in the case of the NAND type flash memory chip 10. In the NAND type flash memory chip 10, a control signal is generated by a command input which is input from the tester 2 and each test of a data program operation, data read operation and data erase operation is performed by a combination of each operation shown in FIG. 4.

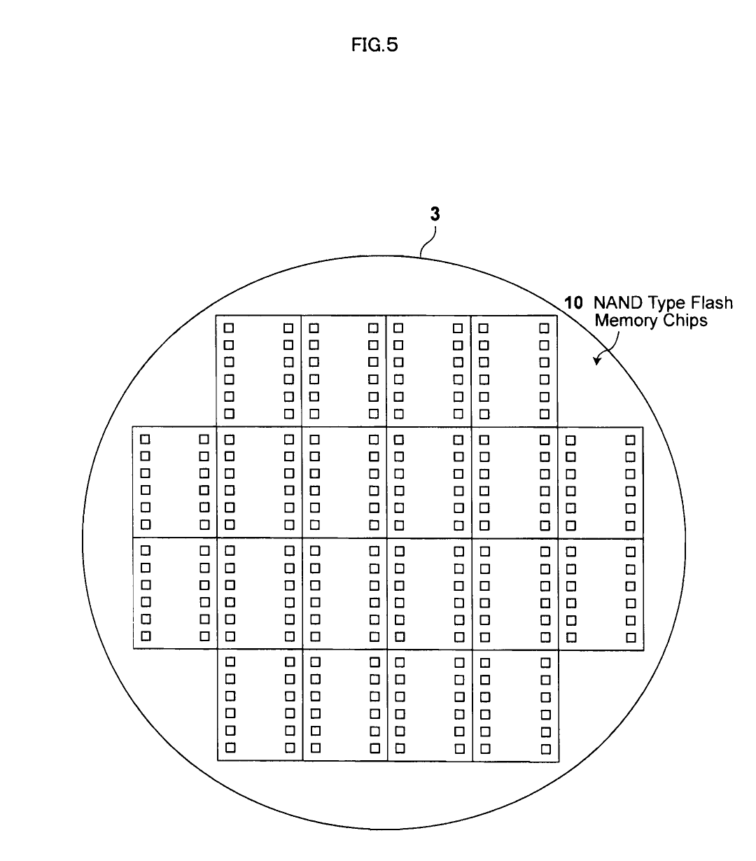

In addition, as stated above, because a total of fifteen pads are arranged in the NAND type flash memory chip 10, for example, in the case where twenty NAND type flash memory chips 10 as shown in FIG. 5 are simultaneously used in a testable test board 3, test pins corresponding to eight input/output pads 12 and five control pads 11 are required for each pad. That is, because 260 pins (13 pins×20 chips) are required in the test board 3, the cost of the tester 2 increases even though a reduction in test time can be achieved. Furthermore, the placement of pads within each NAND flash memory chip 10 in the drawing is shown as a typical example of the connection relationship with the test board 3 and does necessarily match the number of pads shown in FIG. 3.

Below, the embodiments of the present invention will be explained while referring to the diagrams. A NAND type flash memory chip will be explained as an example of the semiconductor memory device related to the embodiments. Furthermore, the same structural elements have the same symbols and to prevent repetition between embodiments a number of explanations will be omitted.

### FIRST EMBODIMENT

In the First embodiment an example of an interface for testing which includes a test pad within a NAND type flash memory chip and an example of reducing the number of pins on a test board 3 will be explained.

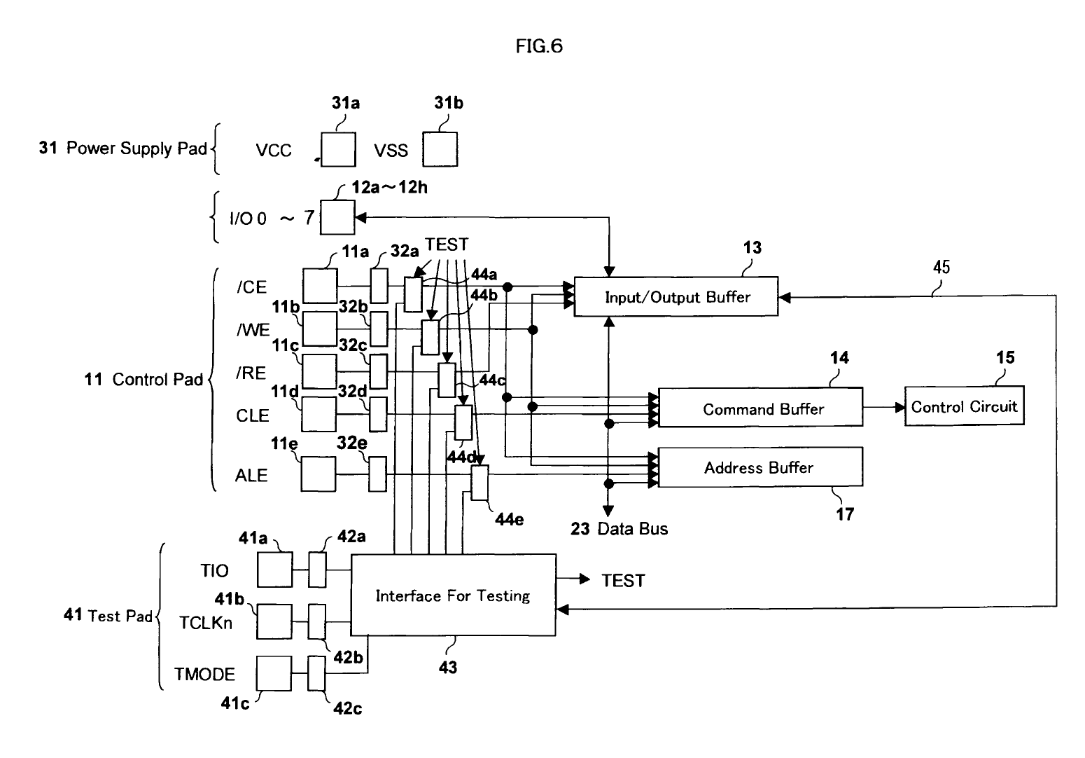

FIG. 6 is a diagram which shows a construction related to inputs and outputs within a NAND type flash memory chip 10 related to the first embodiment. Furthermore, in FIG. 6, the same symbols are used for the same structural elements as in the construction related to input and outputs shown in FIG. 3.

In FIG. 6, a test pad 41 is arranged for sending and receiving commands between a tester 2 related to a test. This test pad 41 includes a TIO pad 41a for inputting and outputting test data, a TCLKn pad 41b for inputting test clock signals, and a TMODE pad 41c for inputting test mode signals. Input pads 42a to 42c are connected to an interface for testing 43 between the test pads 41 and the interface for testing 43.

In the interface for testing 43, test signal switching circuits 44a to 44e which are connected to each input line of the control pad 11 are switched by a test signal TEST and each input line after input buffers 32a to 32e is connected to the input/output buffer 13, command buffer 14 and address buffer 17, or each input line on the side of the test pad 41 is connected to the input/output buffer 13, command buffer 14 and address buffer 17. In the interface for testing 43, in the case where a test mode signal is input from the TMODE pad 41, the test signal switching circuits 44a to 44e are switched by a test signal TEST and each line on the test pad 41 side becomes connected to the input/output buffer 13, the command buffer 14 and the address buffer 17.

Data and clock signals which are input via input buffers 42a to 42c from the test pad 41 are each input to the input/output buffer 13, the command buffer 14 and the address buffer 17 respectively via the test signal switching circuits 44a to 44e by the interface for testing 43. Also, the interface for testing 43 output data which is input via an IO bus for testing 45 connected to the input/output buffer 13 to the TIO pad 41a.

The test pad 41 and the interface for testing 43 are arranged as an interface part (second interface part) for serially inputting and outputting data in one bit units from the tester 2 and performing a test. A test mode in which a test is performed by serially inputting and outputting data in one bit units is called an [X1 mode] in the first and later embodiments. Therefore, in the NAND type flash memory chip 10 related to the first embodiment, there are three pads for testing and compared to the fifteen pads shown in FIG. 3 above, it is possible to greatly reduce the number of pads which are connected with the test board 3.

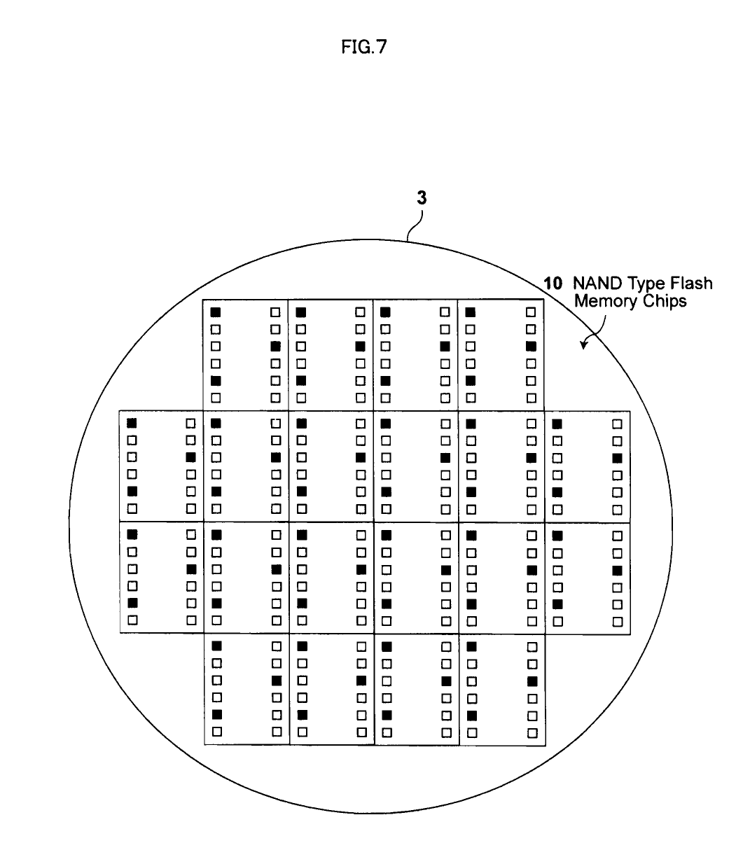

The test board 3 which connects the NAND type flash memory chip 10 arranged with pads used in testing is exemplary shown in FIG. 7. The test board 3 shown in FIG. 7 includes pins which connect twenty NAND type flash memory chips 10. There are sixty pins in this test board 3 (three pins X twenty chips). Therefore, the number of pins in the test board 3 can be considerably reduced compared to the 260 pins of the test board 3 shown in FIG. 5. As a result, it is also possible to reduce the costs of the tester 2.

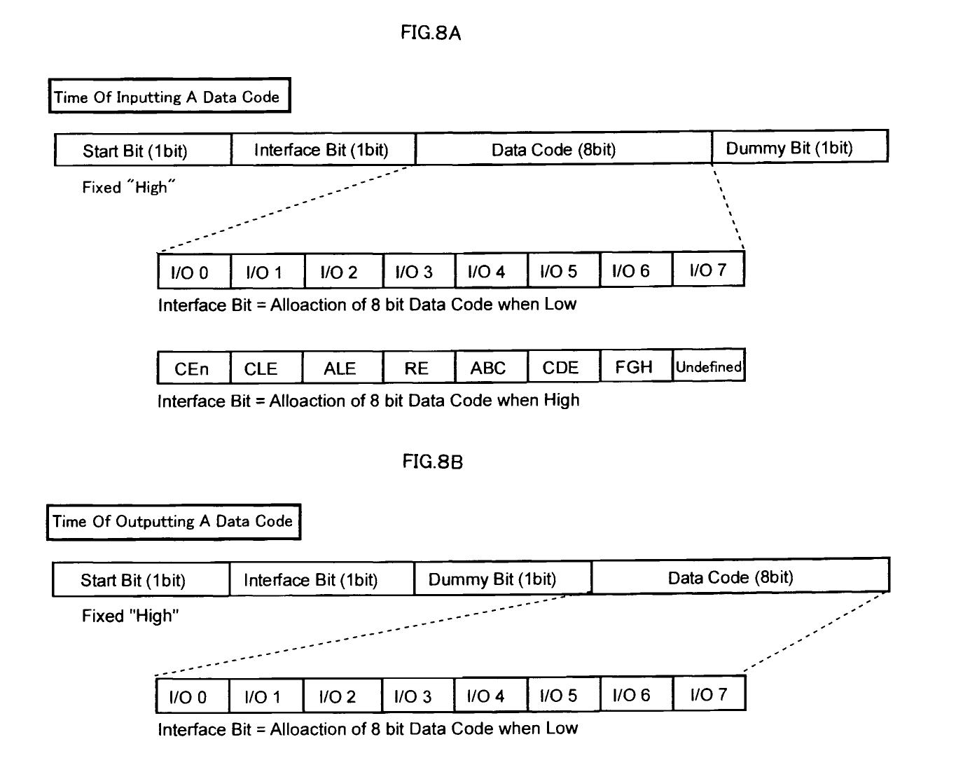

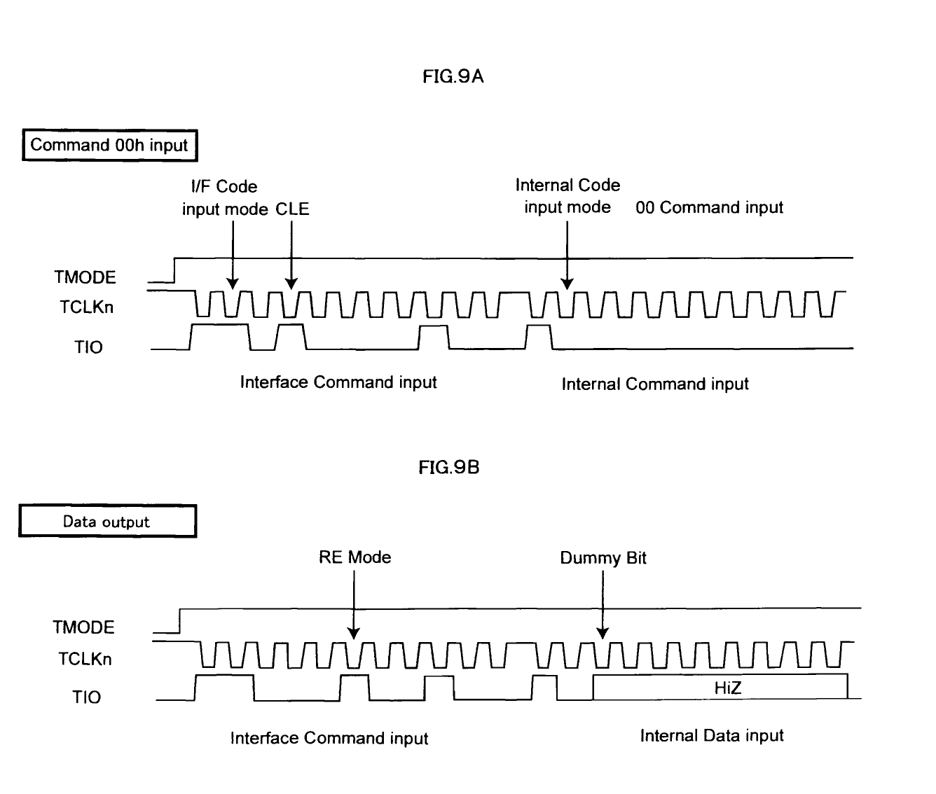

The [X1 mode] which is performed in the NAND type flash memory 10 related to the first embodiment will be explained with reference to FIG. 8 and FIG. 9. FIG. 8 is a diagram which shows an example of each data format at the time of inputting and outputting data codes in [X1 mode]. FIG. 9 is a diagram which shows an example of each waveform in the case a command 00h is input and data is output in [X1 mode].

Each data format at the time of inputting a data code shown in FIG. 8A and outputting a data code shown in FIG. 8B is shown as a time period in which a clock signal TCLKn is counted eleven times, that is, a format which processes eleven bits as one data code.

When a data code shown in FIG. 8A is input, the data code is comprised of eleven bits with the first single bit shown on the left side in the diagram as a [Start Bit] (fixed as “High”), the next one bit is [Interface Bit], the next eight bits are [Data Code] and the next one bit is a [Dummy Bit]. When a data code is input the NAND type flash memory chip 10 recognizes eleven clocks as one group input data when the [Start Bit] (fixed as “High”) is input.

In addition, depending on whether the [Interface Bit] is “High” or “Low”, the NAND type flash memory chip 10 interprets the [Data Code] which is subsequently input differently. In the [Data Code] example shown in FIG. 8A, different data is allocated to each of the bits I/O 0 to I/O 7. In the example shown, when the [Interface Bit] is “High” different commands are allocated to each of the bits I/O 0 to I/O 7 which are included in the [Data Code] comprised of eight bits. Chip enable/CEn is allocated to bit I/O 0, command latch enable/CLE is allocated to bit I/O 4, address latch enable/ALE is allocated to bit I/O 2, read enable/RE is allocated to bit I/O 3, and commands ABC, CDE and FGH are allocated to bits I/O 4 to I/O 6 respectively. Bit I/O 7 is undefined.

When a data code shown in FIG. 8B is output, the data code is comprised of eleven bits with a first single bit shown on the left side in the diagram as the [Start Bit] (fixed as “High”), the next one bit is an [Interface Bit], the next one bit is a [Dummy Bit] and the next eight bits are [Data Code].

The waveform in the case where a command 00h is input based on the data format shown in FIG. 8A will be explained with reference to FIG. 9A.

In the waveform exemplarily shown in FIG. 9A, a data code comprised of eleven bits is input twice. The first time the data code is input, the [Interface Bit]=“High”, /CE=“Low” and CLE=“High”. In the command which is set at this [Interface Bit], the state /CE=“Low”, CLE=“High” is set within the NAND type flash memory chip 10 by inputting the eleventh bit [Dummy Bit]. In addition, in the input of a second data code, “00” data is input as [Interface Bit]=“Low” and applied to a data bus within the NAND type flash memory chip 10 by inputting the eleventh bit [Dummy Bit].

The data format when a data code is output is different to a data format when a data code is input. Whether the state of a data code is made an input state or an output state is determined in the following way. The data code which in input at the next eleven bits is interpreted within the NAND type flash memory chip 10 as a data output state by setting an interface command, that is, a read enable RE bit, to “High” within the [Interface Bit], as shown in FIG. 9B.

The data format when a data code is output is comprised by a [Start Bit] (one bit, fixed as “High”), [Interface Bit] (one bit), [Dummy Bit] (one bit) and [Data Code] (eight bits) as shown in FIG. 8B. As is shown in the input waveform when a data code is output in FIG. 9B, by setting a read enable RE bit within the [Interface Bit] to “High” when a first eleven bit data code is input, it is possible to output data from the second eleven bit group by the NAND type flash memory chip 10.

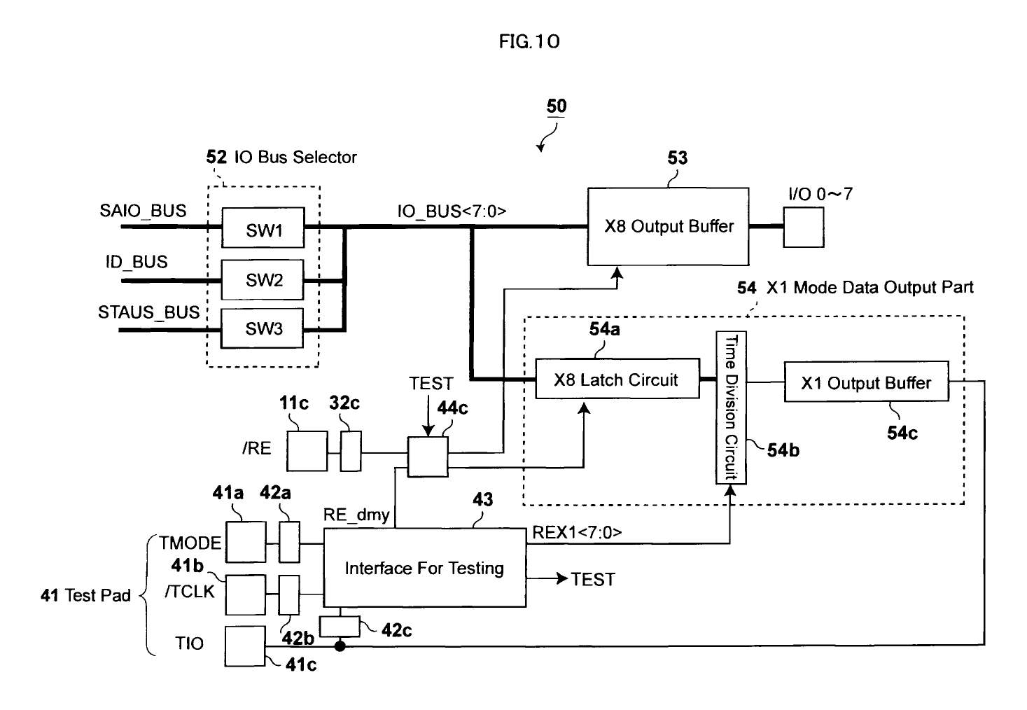

Next, a circuit construction of a data input/output part 50 within the NAND type flash memory chip 10 is shown in FIG. 10. The part shown by a thick line in the diagram is an eight bit wide data bus 51. Furthermore, the data bus 51 is not limited to a width of eight bits. The data input/output part 50 includes IO bus selector 52, X8 output buffer 53 and X1 mode data output part 54.

The IO bus selector 52 includes switches SW1 to SW3. The 10 bus selector 52 selects a bus SAIO_BUS which is connected to an external sense amplifier, an ID_BUS which is connected to a chip ID register and a bus STATUS_BUS which is connected to a status register, via switches SW1 to SW3 and outputs to an IO bus IO_BUS.

The X8 output buffer 53 outputs eight bit data to I/O pads I/O 0 to I/O 7 by synchronizing with a clock by a read enable/RE which is input from the interface for testing 43 via a test signal switching circuit 44.

The X1 mode data output part 54 includes an X8 latch circuit 54a, a time division circuit 54b and an X1 output buffer 54c.

The X8 latch circuit 54a latches eight bit data which is input from IO bus IO_BUS by synchronizing with a clock by a Dummy Bit which is input from the interface for testing 43 via the test signal switching circuit 44.

The time division circuit 54b selects bit by bit eight bit data which is latched by the X8 latch circuit 54a, and outputs to the X1 output buffer 54c based on a bit which is selected by a REX1 signal input from the interface for testing 43. The REX1 signal is generated from a clock signal/TCLK from the fourth bit to the eleventh bit among the above stated eleven bit structure.

Therefore, in the data input/output part 50 in FIG. 10, it is possible to output eight bit parallel data as one bit serial data in accordance with a test mode by switching between the X8 output buffer 53 and the X1 mode data output part 54 in an [X8 mode] and [X1 mode]. As a result, it is possible to reduce the number of pins of a test board 3 which connects a plurality of the NAND type flash memory chips 10 and reduce the costs of the tester 2.

### SECOND EMBODIMENT

In the second embodiment, an example in which the number of test pins of a NAND type flash memory chip and time for testing is reduced will be explained.

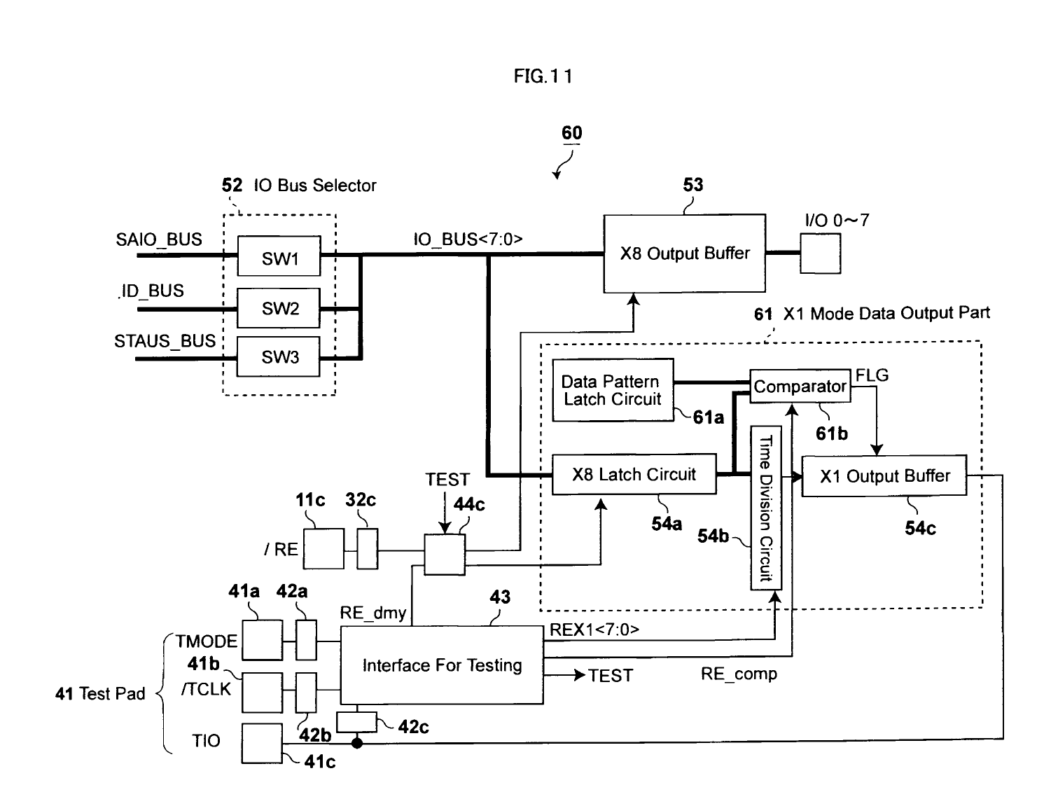

FIG. 11 is a diagram which shows a circuit construction of a data input/output part 60 within the NAND type flash memory chip 10 related to the second embodiment. In the data input/output part 60 shown in FIG. 11, the structural elements which are the same as in the data input/output part 50 shown in FIG. 10 have the same symbols and thus an explanation of its construction is omitted.

An X1 mode data output part 61 includes the X8 latch circuit 54a, the time division circuit 54b, the X1 output buffer 54c, a data pattern latch circuit 61a and a comparator 61b.

The data pattern latch circuit 61a latches data patterns (a110 pattern “00”, a111 pattern “FF”, checker board pattern “55” “AA” etc) for testing in units of eight bits. The data patterns for testing are input in advance and latched before the NAND type flash memory chip 10 is tested by the tester 2.

The comparator 61b compares eight bit data latched by the X8 latch circuit 54a with eight bit data latched by the data pattern latch circuit 61a and outputs a flag FLG which shows the comparison result to the X1 output buffer 54c. The comparator 61b outputs a flag, FLG=0, when all of the eight bit data matches, and outputs a flag, FLG=1, when none of the bits among the eight bits matches. The comparator 61b outputs flags FLG which are the comparisons and comparison results of eight bit data for each cycle of the above stated I/O 0 to I/O 7, when the input of an RE_comp clock signal from the interface for testing 43 starts.

In addition, in the X8 latch circuit 54a, eight bit data which is input from the IO bus IO_BUS is sequentially latched in eight cycles from the clock from the above stated Dummy Bit up to the clock from the I/O 0 to I/O 6 within the above stated data code. That is, in the X8 latch circuit 54a, eight pairs of eight bit data are sequentially latched in eight cycles.

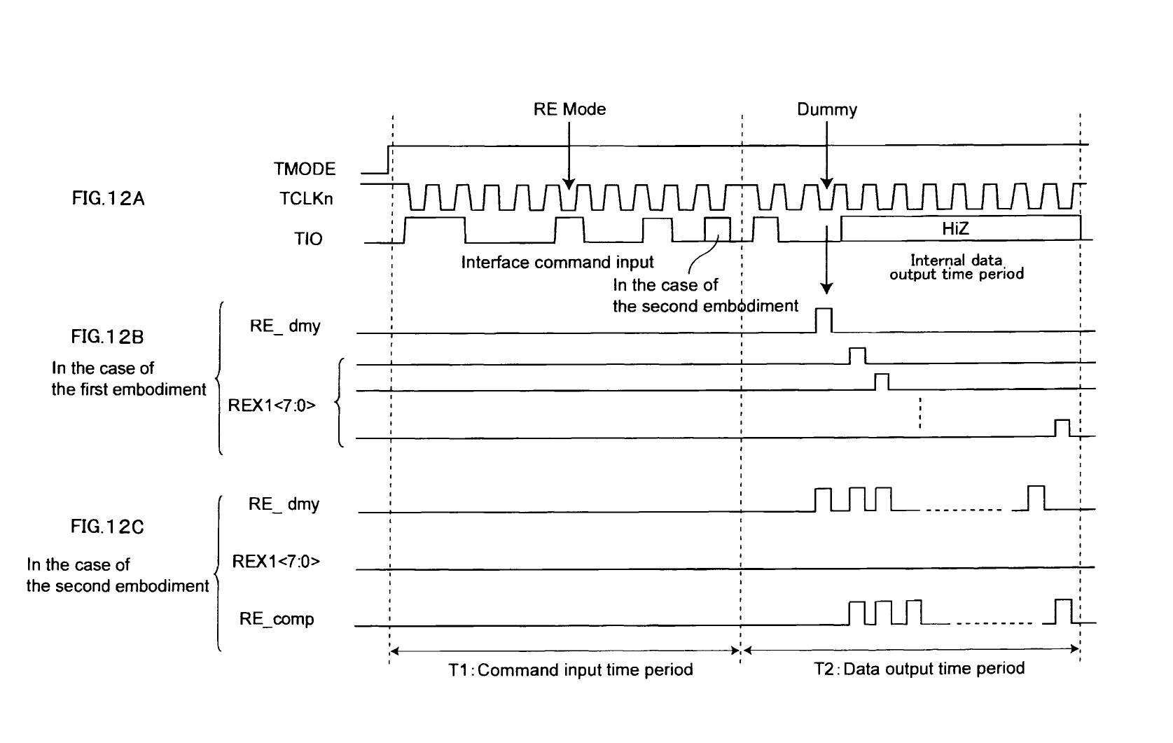

Next, the test operations in the data input/output part 60 within the NAND type flash memory chip 10 related to the second embodiment will be explained while referring to an example of a waveform shown in FIG. 12. Furthermore, the diagram 12A shows a waveform of a signal which is input by the test pad 41, the diagram 12B shows a waveform of a signal related to a test operation in the above stated first embodiment and the diagram 12C shows a waveform of a signal related to a test operation of the second embodiment.

In FIG. 12, because read enable/RE (“High”) is set by eleven bit input data which is input from the tester 2 in a command input time period which is shown as the time period T1, it is interpreted within the NAND type flash memory chip 10 as data output.

Next, in FIG. 12A, in the data output time period shown as time period T2, in the case of the first embodiment, 8 bit data which is input from the IO bus IO_BUS is latched by the X 8 latch circuit 54a by a Dummy Bit within the 11 bit data code input form the tester 2. In addition, in FIG. 12A, in the output time period shown as the time period T2, in the case if the second embodiment, 8 bit data which is input from the 10 bus IO_BUS is latched by the X 8 latch circuit 54a by 8 clocks up to a clock by I/O 0 to I/O 6 within the data code and a Dummy Bit within the 11 bit data code input form the tester 2.

At this time, in the test operation related to the first embodiment shown in FIG. 12B, one bit of data is output bit by bit to the X1 output buffer 54c from the time division circuit 54b in a clock cycle of an REX1<7:0> signal. That is, in the test operation related to the first embodiment, eight bits which are latched by the Dummy Bit are output in parallel from the X1 output buffer 54c as one bit serial data. As a result, in the data input/output part 50 related to the first embodiment, eleven clocks are required to output eight bit parallel data as serial data lengthening the time required for testing.

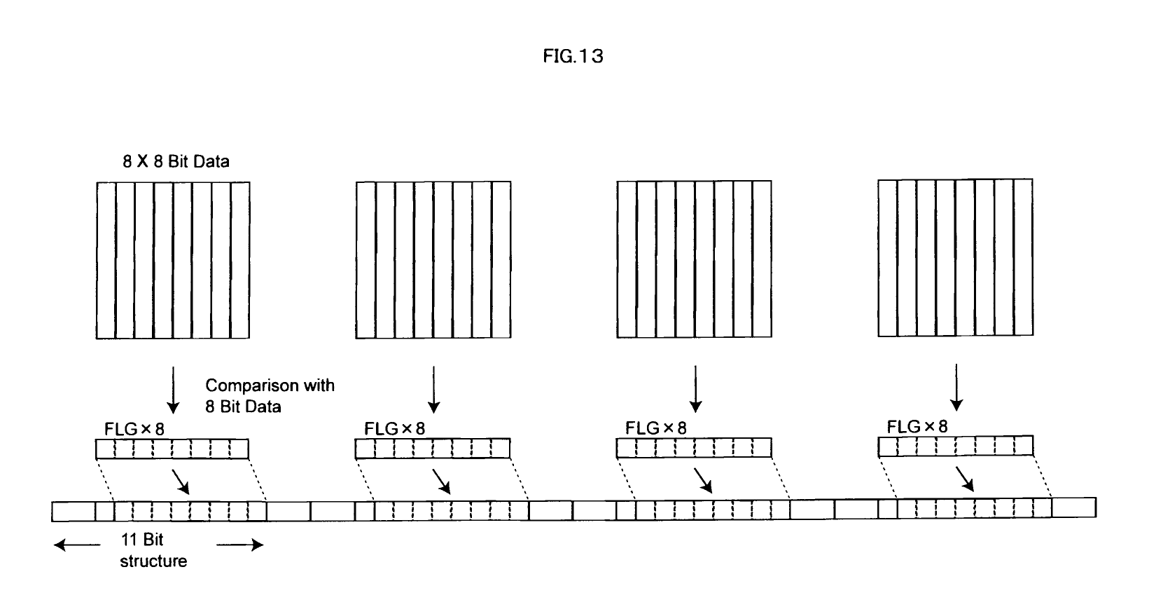

Unlike the operation in FIG. 12B, in the test operation related to the second embodiment shown in FIG. 12C, when input of the RE_comp clock signal from the interface for testing 43 begins the comparator 61b sequentially outputs flags FLG which are an eight bit data comparison for each clock of I/O 0 to I/O 7 (comparison of eight bit data latched by the X8 latch circuit 54a with eight bit data latched by the data pattern latch circuit 61) and a comparison result. As a result, in the data input/output part 60 related to the second embodiment, it is possible to output data which shows whether there are errors among the eight bits of data in each cycle of I/O 0 to I/O 7 and reduce testing time. That is, in the comparator 61b it is possible to perform a comparison process of eight groups of eight bit data in eight cycles of the I/O 0 to I/O 7 as shown in FIG. 13 and obtain eight flags FLG which show the comparison results. It is also possible to output serial data which includes eight flags FLG by the clock cycles of the eleven bit construction shown in FIG. 13, to the X1 output buffer 54c.

Furthermore, the data format which is input in the command input time period shown in FIG. 12A is different to the data format shown in FIG. 9A. In the second embodiment, because the data which is output in eight cycles is eight times greater, for example, an undefined part of I/O 7 within the Interface Bit shown in FIG. 8A is used. That is, in the data format shown in FIG. 12A, when I/O 7 within the Interface Bit is “High”, an output mode in which data is eight times greater is assigned. When this I/O 7 bit “High” setting is input, the NAND type flash memory chip 10 is interpreted as being in this eight times greater output mode and the test mode which outputs the above stated eight bit data comparison and comparison result is realized.

Therefore, in the NAND type flash memory chip 10 related to the second embodiment, the number of pads for testing can be reduced, the number pins of the test board 3 and the costs of the tester 2 can be significantly reduced and it is also possible to realize a reduction in the time required for testing.

### THIRD EMBODIMENT

In the third embodiment, it is possible to reduce the number of test pins of a NAND type flash memory chip. In the third embodiment, an example which makes a test of sixteen bit data possible and reduces the time required for testing will be explained.

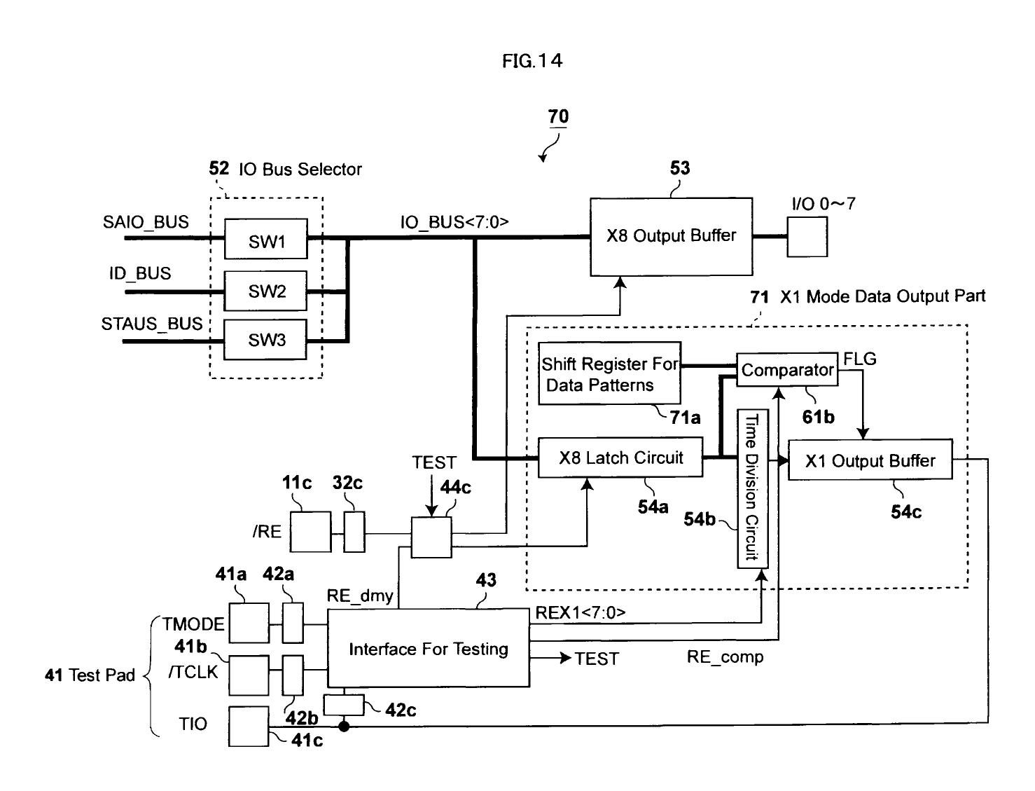

FIG. 14 is a diagram which shows a circuit structure of a data input/output part 70 within the NAND type flash memory 10 related to the third embodiment. In the data input/output part 70 in FIG. 14, the same structural elements as in the data input/output part 50 shown in FIG. 10 and the data input/output part 60 shown in FIG. 11 have the same symbols and an explanation of those structural elements will be omitted here.

An X1 mode data output part 71 includes the X8 latch circuit 54a, the time division circuit 54b, the X1 output buffer 54c, a shift register for a data pattern 71a and the comparator 61b.

The shift register for a test pattern 71a stores two eight bit data patterns and alternately outputs the two eight bit patterns via the shift register to the comparator 61a.

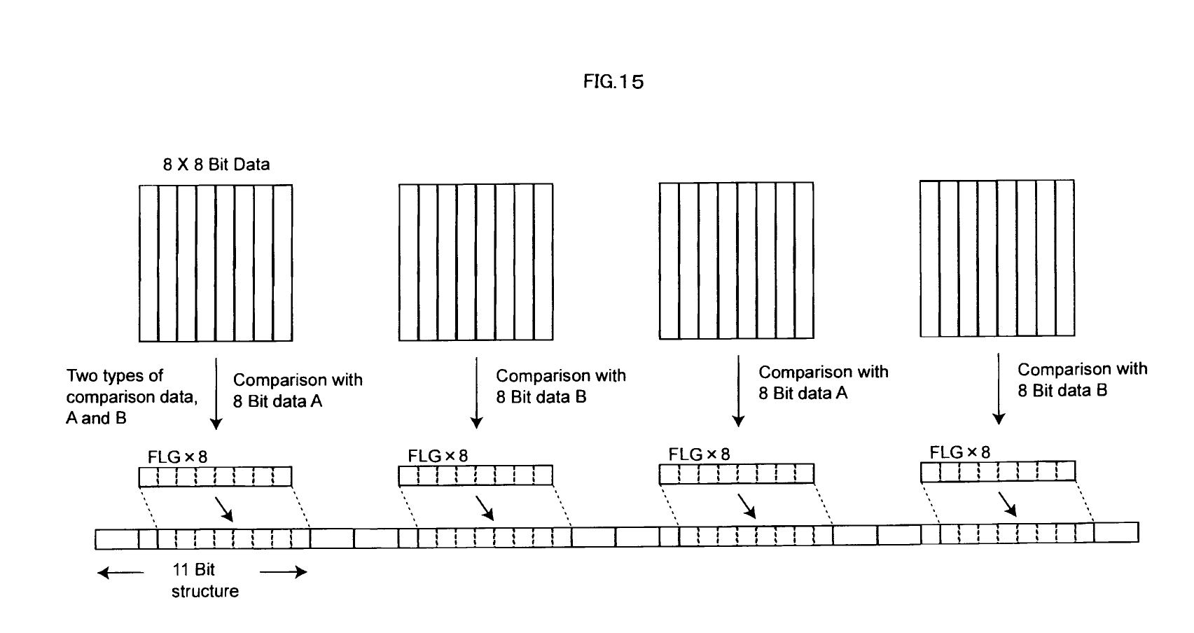

By using the shift register for data patterns 71a it is possible to compare two types of certain data pattern, A and B, with a sixteen bit structure shown in FIG. 15, and output that comparison result. As a result, it is possible to compare more complex data patterns. Therefore, in the above stated second embodiment, a comparison with only eight bit data patterns was possible, however in the third embodiment a comparison with sixteen bit data patterns is possible which further reduces the time required for testing. Here, an example using 2×8 bit data was shown, however applications with 3×8 bit data and 4×8 bit data are also possible.

### FOURTH EMBODIMENT

In the fourth embodiment the number of test pins of a NAND type flash memory chip can be reduced. In addition, an example in which it is possible to output detailed fail bit data as a test result and reduce the time required for testing will be explained.

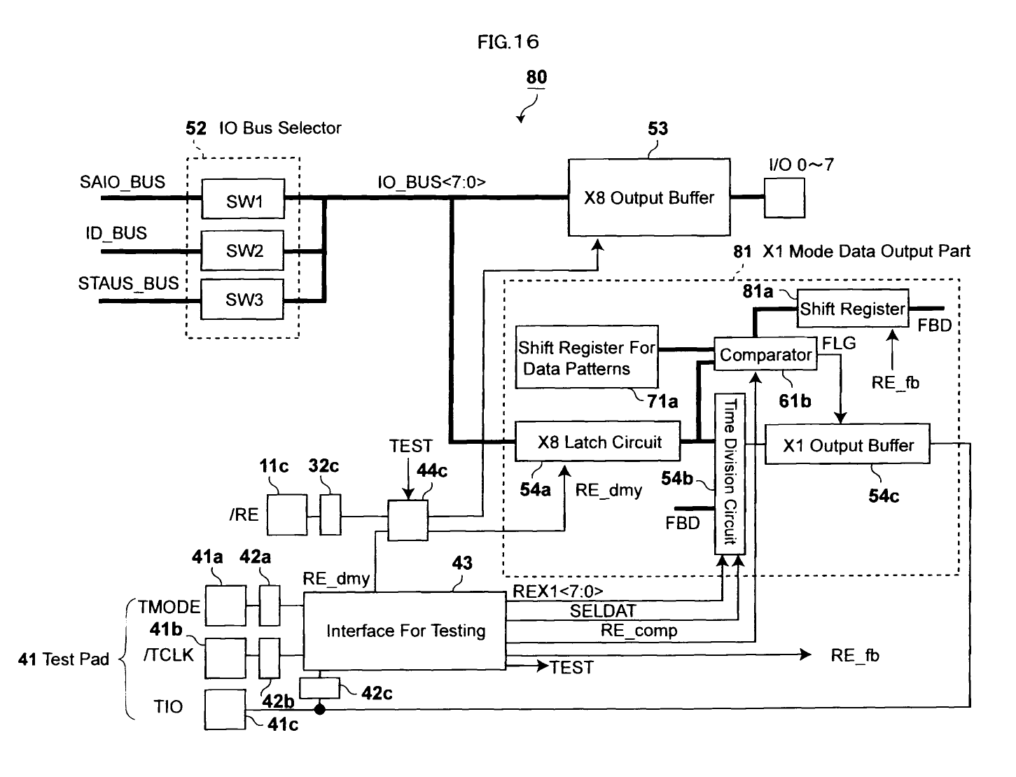

FIG. 16 is a diagram which shows a circuit structure of a data input/output part 80 within the NAND type flash memory chip 10 related to the fourth embodiment. The structural elements in the data input/output part 80 shown in FIG. 16 which are the same as in the data input/output part 50 shown in FIG. 10, the data input/output part 60 shown in FIG. 11 and the data input/output part 70 shown in FIG. 14 have the same symbols and their explanation will be omitted here.

An X1 mode data output part 81 includes the X8 latch circuit 54a, the time division 54b, the X1 output buffer 54c, the shift register for data patterns 71a, the comparator 61b and a shift register 81a.

The shift register 81a stores comparison results for eight cycles of 8 bit data and sequentially outputs fail bit data FBD which shows in detail comparison results for eight cycles of 8 bit data, to the time division circuit 54b in a clock cycle of a fail bit read signal RE_fb input from the interface for testing 43.

The time division circuit 54b switches usual data which is input from the X8 latch circuit 54a with the fail bit data FBD which is input from the shift register 81a and outputs to the X1 output buffer 54c according to a selection signal SELDAT which is input from the interface for testing 43.

The comparator 61b sequentially outputs flags FLG which shows comparison results for 8×8 bit data, to the X1 output buffer 54c in 8 cycles, and sequentially outputs comparison results for 8 bit data (8 bit data which includes comparison results for each bit of data) to the shift register 81a.

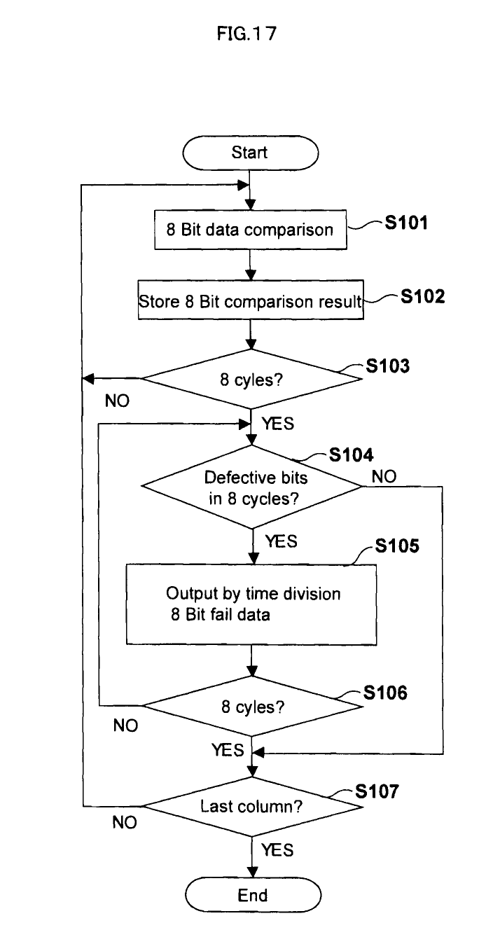

Next, a test operation with the NAND type flash memory chip 10 related to the fourth embodiment will be explained while referring to the flowchart shown in FIG. 17.

When a test operation begins in FIG. 17, the comparator 61b in FIG. 16 compares 8 bit data which is latched by the X8 latch circuit 54a, with an 8 bit data pattern input from the shift register for data patterns 71a. The comparator 61b outputs 8 bit data which includes comparison results to the shift register 81a and also outputs flags FLG (1 bit data) which show the comparison results for this 8 bit data, to the X1 output buffer 54c (step S101). At this time, the comparator 61b performs a comparison with data patterns of 8 bit data for each 1 cycle as explained in the above stated second embodiment, and sequentially outputs flags FLG which shows the data comparison results for this 8 bit data, to the X1 output buffer 54c. In addition, the comparator 61b outputs comparison results of 8 bit data (8 bit data including comparison results for each 1 bit) to the shift register 81a.

Next, the shift register 81a stores 8 bit data which is input from the comparator 61b (step S102). Then, the comparator 61b and the shift register 81a repeat processing of the above stated steps S101 and S102 for 8 cycles (step S103). The shift register 81a sequentially stores 8 bit data which input from the comparator 61b whether there are no matches (defective bits) or not within the 8 bit data by repeating this 8 cycle operation. Two types of data, namely data “0” which shows a match and data “1” which shows a non-match are included for each compared bit in the 8 bit data stored in the shift register 81a. In addition, the comparator 61b sequentially outputs flags FLG which shows comparison results of 8×8 bit data, to the X1 output buffer 54c.

Next, the shift register 81a determines whether there are defective bits in the 8 cycles of comparison processing of 8×8 bit data (step S104). If there are no defective bits (step S104: NO), the process shifts to step S107. In addition, if the shift register 81a determines that there are defective bits (step S104: YES), the process shifts to step S105.

Next, the shift register 81a outputs by time division the stored 8 bit data as fail bit data FBD with an 11 bit structure according to a clock cycle of a fail bit read signal RE_fb input from the interface for testing 43 (step S105). Then, the shift register 81a repeats for 8 cycles the output process by time division of the fail bit data FBD in the above stated step S105. (step S106).

Next, the comparator 61b confirms whether a data comparison process has been performed up to the last column with the same page (step S107). If the process has not been performed up to the last column (step S107: NO), the process returns to step S101 and the processes from step S101 to step S106 are repeated. In addition, if the process has been performed up to the last column (step S107: YES), then the test operation is complete.

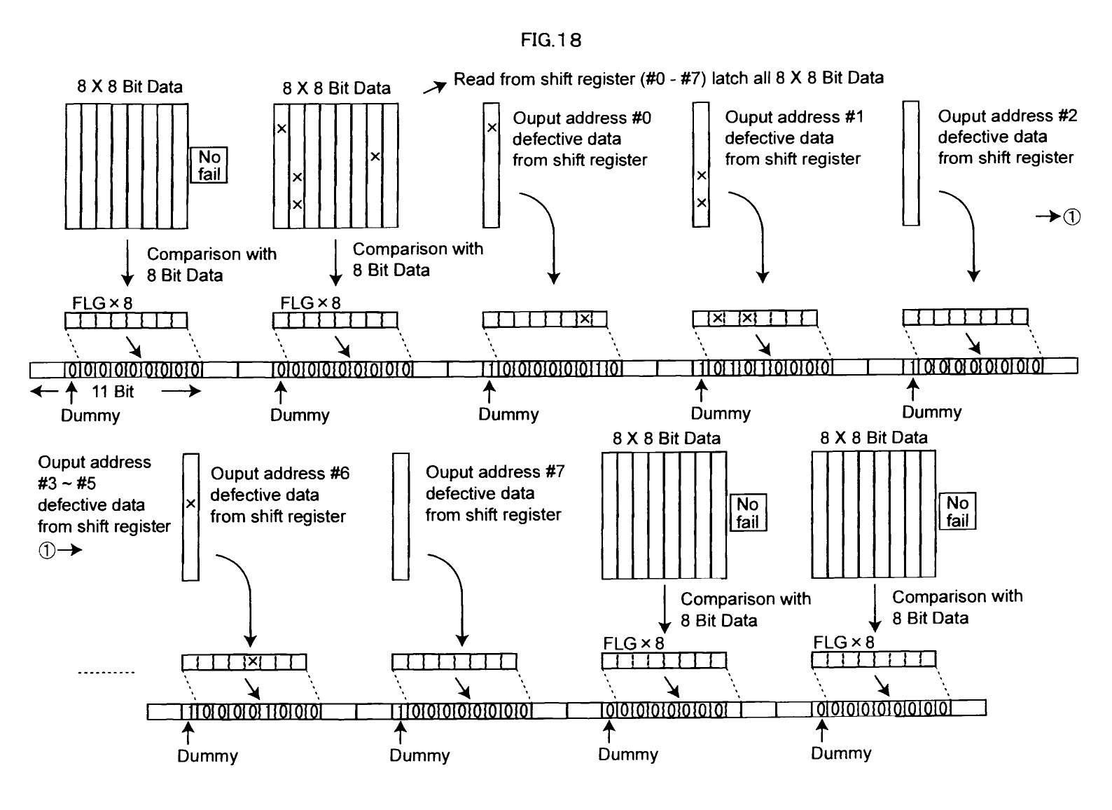

Next, specific examples of a comparison operation of 8 bit data and an output operation of fail bit data FBD by the test operation described above will be explained while referring to FIG. 18.

In FIG. 18, a case where there are no defective bits in a first comparison process of 8×8 bit data is shown. In this case, the comparator 61b outputs flags FLG (1 bit data) which show comparison results for 8 bit data, to the X1 output buffer 54c according to an RE_comp clock signal input from the interface for testing 43. The flags FLG=0 when all of the 8 bit data matches as stated above.

In FIG. 18, a case where there are defective bits in the next comparison process of 8×8 bit data is shown. In this case, the comparator 61b similarly sequentially outputs flags FLG (1 bit data) which show comparison results for 8×8 bit data, to the X1 output buffer 54c according to an RE_comp clock signal input from the interface for testing 43. The flags FLG=1 when at least one bit of the 8 bit data doesn't match as stated above. In addition, the shift register 81a correlates all the data from the address #0 to the address #7 and latches all the comparison results of 8×8 bit data input from the comparator 61b and outputs by time division fail bit data FBD for each of the stored 8 bit data according to a clock cycle of a fail bit read signal RE_fb input from the interface for testing 43.

In FIG. 18, an example is shown where data is set which shows whether a flag FLG or a fail bit data FBD is output to the Dummy bit which is included in a data code when the data code which has an 11 bit structure which includes flags FLG for 8 bits and fail bit data FBD for 8 bits, is output. For example, when a flag FLG is output, the Dummy Bit is set to 0, and when fail bit data is output, the Dummy Bit is set to 1.

In FIG. 18, after a flag FLG which includes a defective bit in the above stated 8×8 bit data, is sequentially output, fail bit data FBD with an 8 bit structure which includes defective bits correlated with a position (from address #0 to address #7) in which defective bits in 8 bit data units occur, is sequentially output from the shift register 81a.

Specifically, as shown in FIG. 18, 8 bit data on the left side of the diagram within the 8×8 bit data, that is, one defective bit is included in the 8 bit data stored in the address #0 within the shift register 81a. Fail bit data FBD of 8 bits which includes data “1” (normal bit is “0”) which shows the location where this defective bit occurs, is output as a data code with an 11 bit structure. Then, the second from the left 8 bit data within the 8×8 bit data, that is, two defective bits are included in the 8 bit data stored in the address #1 within the shift register 81a. Fail bit data FBD of 8 bits which includes data “1” (normal bit is “0”) which shows the location where this defective bit occurs, is output as a data code with an 11 bit structure. Furthermore, X in the diagram indicates a defective bit.

Next, third from the left 8 bit data within the 8×8 bit data, that is, no defective bits are included in the 8 bit data stored in the address #2 within the shift register 81a. As a result, fail bit data FBD of 8 bits which are all data “0”, is output as a data code with an 11 bit structure. The remaining 5×8 but data are similarly output by a data code format with an 11 bit structure. When these fail bit data FBD are output the Dummy Bit is set at “1”.

As above, in the fourth embodiment, at the time of a test operation, flags FLG which show the presence of defective bits are output as an 8 bit data comparison result and detailed fail bit data FBD which shows the location of this defective bits occurs are also output. As a result, it is possible to know in which 8 bit data defective bits are included during a comparison process of 8×8 bit data and it is also possible to know where this defective bit occurs.

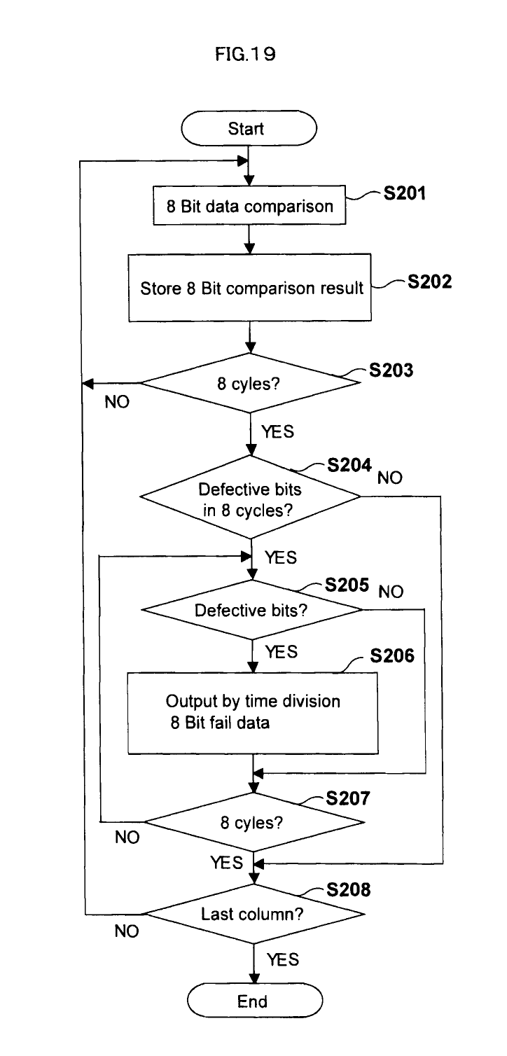

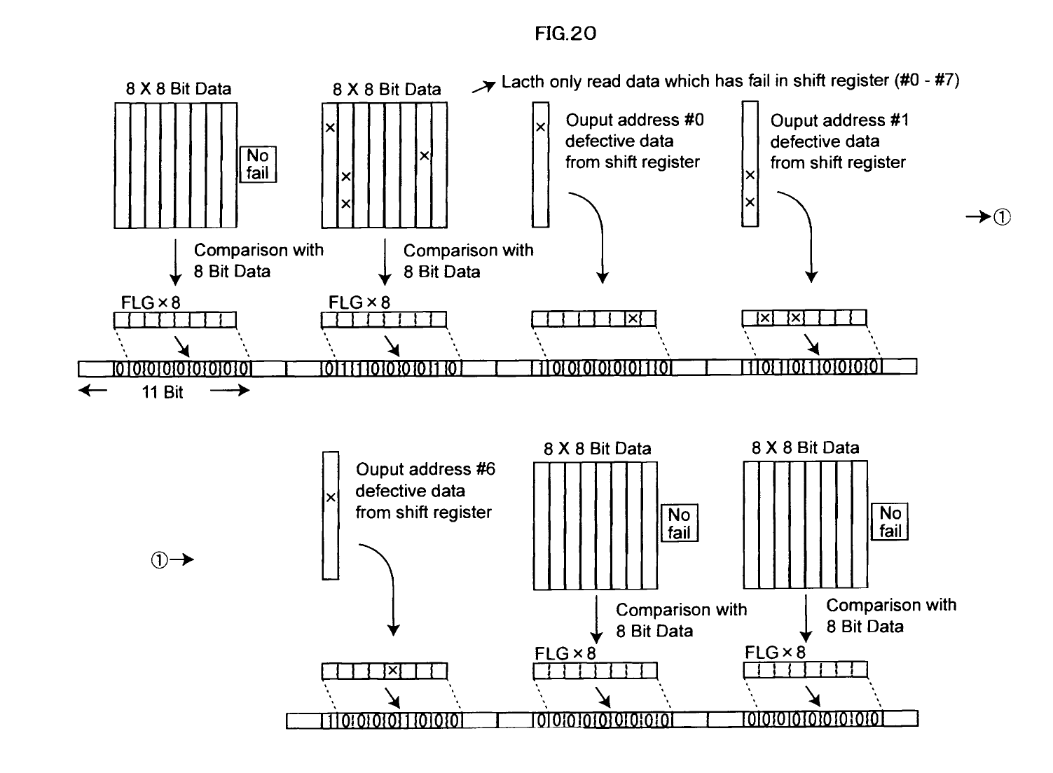

Next, another example of a test operation in the fourth embodiment will be explained by referring to the flowchart in FIG. 19 and the specific example of a comparison process and a comparison result shown in FIG. 20.

When the test operation begins in FIG. 19, the comparator 61b in FIG. 16 compares 8 bit data which is latched by the X8 latch circuit 54a, with an 8 bit data pattern input from the shift register for data patterns 71a. The comparator 61b outputs 8 bit data which includes a comparison result to the shift register 81a and also outputs flags FLG (1 bit data) which show this 8 bit data comparison result, to the X1 output buffer 54c (step S201). At this time, the comparator 61b performs a comparison of data patterns with 8 bit data for each 1 cycle as explained in the above stated second embodiment, and sequentially outputs flags FLG which shows the data comparison results for this 8 bit data, to the X1 output buffer 54c. In addition, the comparator 61b outputs comparison results of 8 bit data (8 bit data including comparison results for each 1 bit) to the shift register 81a.

Next, the shift register 81a stores only 8 bit data which includes a defective bit among the 8 bit data which is input from the comparator 61b (step S202). Then, the comparator 61b and the shift register 81a repeat processing of the above stated steps S201 and S202 for 8 cycles (step S203). The shift register 81a sequentially stores only 8 bit data which has a non-match (defective bit) within the 8 bit data among the 8 bit data which input from the comparator 61b by repeating this 8 cycle operation. Two types of data, namely data “0” which shows a match and data “1” which shows a non-match are included for each compared bit in the 8 bit data stored in the shift register 81a. In addition, the comparator 61b sequentially outputs flags FLG which show comparison results of 8×8 bit data, to the X1 output buffer 54c.

Next, the shift register 81a determines whether there are defective bits in the 8 cycles of comparison processing of 8×8 bit data (step S204). If there are no defective bits (step S204: NO), the process shifts to step S208. In addition, if the shift register determines that there are defective bits (step S204: YES), the process shifts to step S205.

In step S205, the shift register 81a further determines whether there are defective bits in the stored 8 bit data. If there are no defective bits (step S205: MO), the process shifts to step S207. In addition, if the shift register determines that there are defective bits (step S205: YES), the process shifts to step S206.

In step S206, the shift register 81a outputs by time division the 8 bit data which includes defective bits as fail bit data FBD. Then, the shift register 81a repeats for 8 cycles the output process by time division of the fail bit data FBD in the above stated step S206. (step S207).

Next, the comparator 61b confirms whether a data comparison process has been performed up to the last column within the same page (step S208). If the process has not been performed up to the last column (step S208: NO), the process returns to step S201 and the processes from step S201 to step S207 are repeated. In addition, if the process has been performed up to the last column (step S208: YES), then the test operation is complete.

Next, the comparison operation of 8 bit data and a specific example of an output operation of fail bit data FBD by the above stated test operation will be explained while referring to FIG. 20.

In FIG. 20, a case where there are no defective bits in a first comparison process of 8×8 bit data is shown. In this case, the comparator 61b outputs flags FLG (1 bit data) which show comparison results for 8 bit data, to the X1 output buffer 54c according to an RE_comp clock signal input from the interface for testing 43. The flags FLG=0 when all of the 8 bit data matches as stated above.

In FIG. 20, a case where there are defective bits in the next comparison process of 8×8 bit data is shown. In this case, the comparator 61b similarly sequentially outputs flags FLG (1 bit data) which show comparison results for 8×8 bit data, to the X1 output buffer 54c according to an RE_comp clock signal input from the interface for testing 43. The flags FLG=1 when at least one bit of the 8 bit data doesn't match as stated above. In addition, the shift register 81a correlates all the data from the address #0 to the address #7 and latches only the 8 bit data which has defective bits from among the 8×8 bit data comparison results input from the comparator 61b. That is, among the 8×8 bit data shown in FIG. 20, only 3×8 bit data which include defective bits are latched to the address #0, #1, #6 within the shift register 81a. Then, the shift register 81a outputs by time division fail bit data FBD for each of the stored 8 bit data according to a clock cycle of a fail bit read signal RE_fb input from the interface for testing 43.

In FIG. 20, an example is shown where data is set which shows whether a flag FLG or a fail bit data FBD is output to the Dummy bit which is included in a data code when the data code which has an 11 bit structure which includes flags FLG for 8 bits and fail bit data FBD for 8 bits, is output. For example, when a flag FLG is output, the Dummy Bit is set to 0, and when fail bit data is output, the Dummy Bit is set to 1.

In FIG. 20, after a flag FLG which includes a defective bit in the above stated 8×8 bit data, is output, fail bit data FBD with an 8 bit structure which includes defective bits correlated with a position (from address #0 to address #7) in which defective bits in 8 bit data units occur, is sequentially output from the shift register 81a.

Specifically, as shown in FIG. 20, 8 bit data on the left side of the diagram within the 8×8 bit data, that is, one defective bit is included in the 8 bit data stored in the address #0 within the shift register 81a. File bit data FBD of 8 bits which includes data “1” (normal bit is “0”) which shows the location where this defective bit occurs, is output as a data code with an 11 bit structure. Then, the second from the left 8 bit data within the 8×8 bit data, that is, two defective bits are included in the 8 bit data stored in the address #1 within the shift register 81a. File bit data FBD of 8 bits which includes data “1” (normal bit is “0”) which shows the location where this defective bit occurs, is output as a data code with an 11 bit structure. Furthermore, X in the diagram indicates a defective bit.

Next, the seventh 8 bit data from the left within the 8×8 bit data, that is, one defective bit is included in the 8 bit data stored in the address #6 within the shift register 81a. File bit data FBD of 8 bits which includes data “1” (normal bit is “0”) which shows the location where this defective bit occurs, is output as a data code with an 11 bit structure. When these fail bit data FBD are output the Dummy Bit is set at “1”.

As above, in the fourth embodiment, at the time of another test operation, flags FLG which show the presence of defective bits are output as an 8 bit data comparison result and only detailed fail bit data FBD which shows the location of this defective bit are output. As a result, it is possible to further reduce the time required for testing.

### FIFTH EMBODIMENT

In the fifth embodiment the number of test pins of a NAND type flash memory chip can be reduced. In addition, an example in which it is possible to output address data of a defective bit as a test result and reduce the time required for testing will be explained.

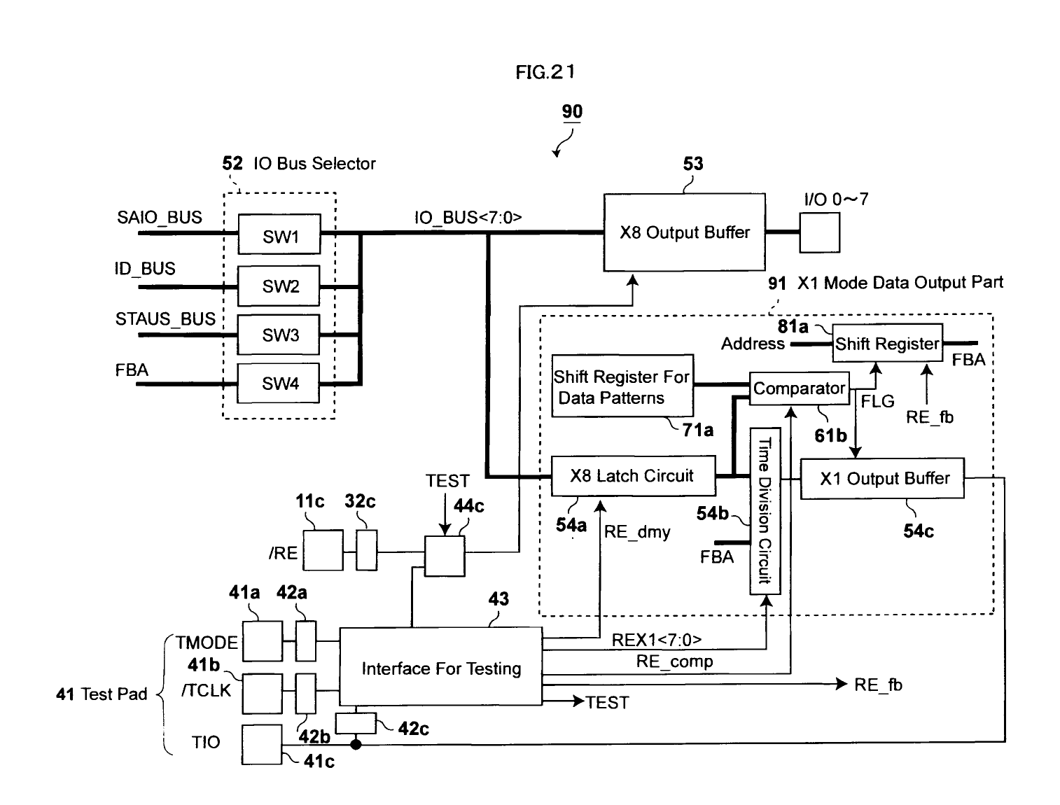

FIG. 21 is a diagram which shows a circuit structure of a data input/output part 90 within the NAND type flash memory chip related to the fifth embodiment. In the data input/output part 90 shown in FIG. 21, the structural elements which are the same as in the data input/output part 50 shown in FIG. 10, the data input/output part 60 shown in FIG. 11, the data input/output part 70 shown in FIG. 14 and the data input/output part 80 shown in FIG. 16, have the same symbols and this an explanation of these structural elements will be omitted.

An X1 mode data output part 91 includes the X8 latch circuit 54a, the time division circuit 54b, the X1 output buffer 54c, the shift register for data patterns 71a, the comparator 61b and the shift register 81a.

The comparator 61b sequentially outputs flags FLG which shows comparison results for 8×8 bit data, to the X1 output buffer 54c and the shift register 81a in 8 cycles.

The shift register 81a stores only address data of a defective bit among the flags FLG which are input from the comparator 61b and outputs address data of the stored defective bit as fail bit address data FBA after reading of the data from the memory cell array 21 is complete. This fail bit address data FBA is output to the time division circuit 54b via an output FBA bus.

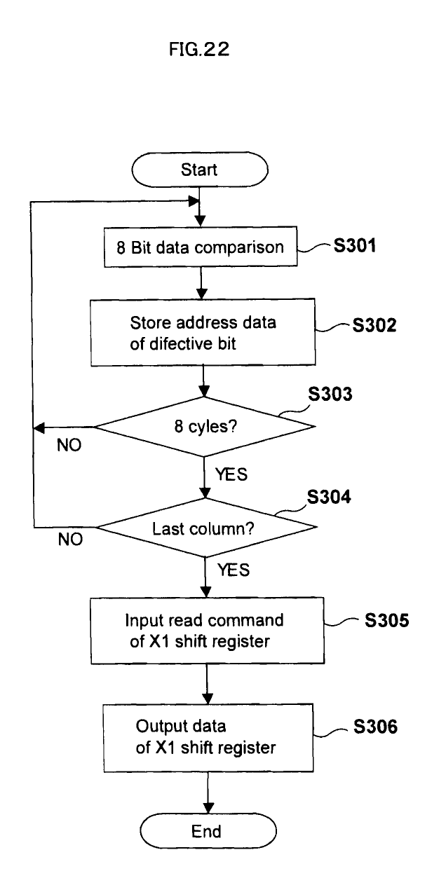

Next, a test operation within the NAND type flash memory chip 10 related to the fifth embodiment will be explained while referring to the flowchart in FIG. 22.

When the test operation begins in FIG. 22, the comparator 61b in FIG. 21 compares 8 bit data which is latched by the X8 latch circuit 54a, with an 8 bit data pattern input from the shift register for data patterns 71a. The comparator 61b outputs 8 bit data which includes a comparison result to the shift register 81a and also outputs flags FLG (1 bit data) which show this 8 bit data comparison result, to the X1 output buffer 54c (step S301). At this time, the comparator 61b performs a comparison of data patterns and 8 bit data for each 1 cycle as explained in the above stated second embodiment, and sequentially outputs flags FLG which shows the data comparison results for each 8 bit data, to the X1 output buffer 54c. In addition, the comparator 61b outputs comparison results of 8 bit data to the shift register 81a.

Next, the shift register 81a reads and stores only address data of 8 bit data which includes a defective bit among the 8 bit data which is input from the comparator 61b (step S302). Then, the comparator 61b and the shift register 81a repeat processing of the above stated steps S301 and S302 for 8 cycles (step S303). The shift register 81a sequentially stores only address data of 8 bit data which has a non-match (defective bit) within the 8 bit data among the 8 bit data which input from the comparator 61b by repeating this 8 cycle operation.

Next, the comparator 61b confirms whether a data comparison process has been performed up to the last column within the same page (step S304). If the process has not been performed up to the last column (step S304: NO), the process returns to step S301 and the processes from step S301 to step S303 are repeated. In addition, if the process has been performed up to the last column (step S208: YES), then the process shifts to step S305.

Next, when a X1 shift register read command is input, the output bus FBA of the shift register 81a is selected as the input of the time division circuit 54b (step S302). The shift register 81a outputs address data in 8 bit units to the time division circuit 81a via the FBA bus according to a RE_fb clock signal input from the interface for testing 43, outputs by time division the stored 8 bit data as fail bit data with an 11 bit structure (step S306) and the present test operation is complete.

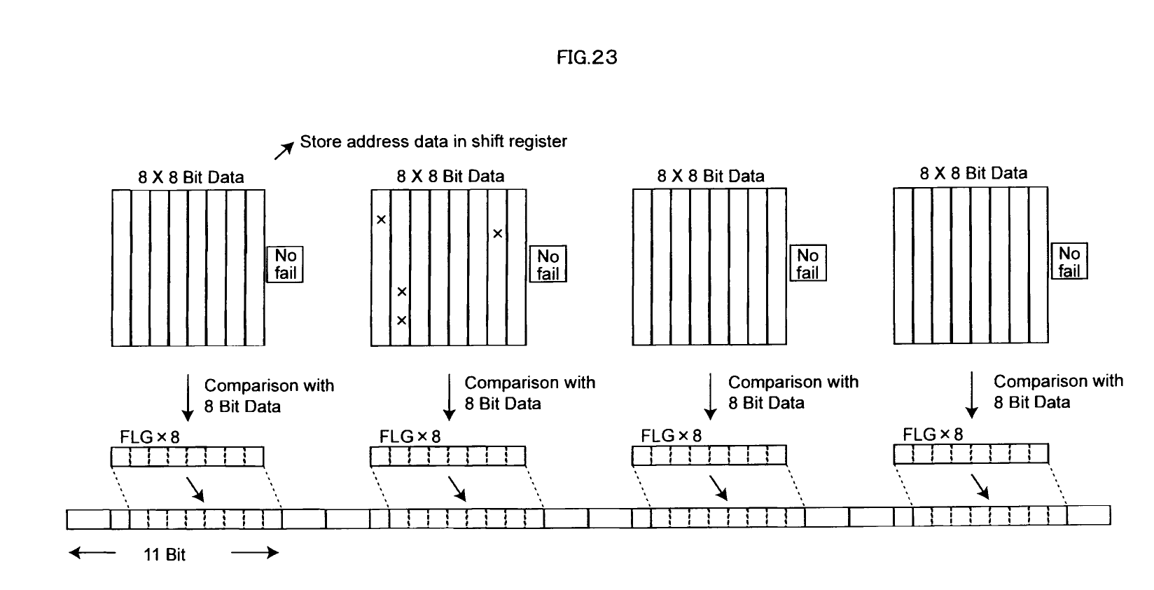

Next, a specific example of an 8 bit data comparison operation and an output operation of a data code will be explained while referring to FIG. 23.

In FIG. 23, a case where there are no defective bits in a first comparison process of 8×8 bit data is shown. In this case, the comparator 61b outputs flags FLG (1 bit data of 0) which show comparison results for 8 bit data, to the X1 output buffer 54c according to an RE_comp clock signal input from the interface for testing 43. The flags FLG=0 when all of the 8 bit data matches as stated above. Then, the X1 output buffer 54c outputs as a data code with an 11 bit structure which includes flags FLG (8×1 bit data of only 0) of 8 bits.

In FIG. 23, a case where there are defective bits in the next comparison process of 8×8 bit data is shown. In this case, the comparator 61b similarly sequentially outputs flags FLG (1 bit data) which show comparison results for 8×8 bit data, to the X1 output buffer 54c according to an RE_comp clock signal input from the interface for testing 43. The flags FLG=1 when at least one bit among the 8 bit data doesn't match as stated above. Then, the X1 output buffer 54c outputs as a data code with an 11 bit structure which includes flags FLG (1 bit data of 0 and 1) of 8 bits. In this case, four defective bits are included in 8×8 bit data and address data of these defective bits are stored in the shift register 81a.

In FIG. 23, in the comparison processing of 8×8 bit data with no defective bits, a data code with an 11 bit structure which includes flags FLG (8×1 bit data only of 0) of 8 bit data are similarly output from the X1 output buffer 54c.

After outputting of a data code is complete, address data of defective bits stored in the shift register 81a is sequentially output as fail bit address data FBA according to a clock cycle of a fail bit read signal RE_fb input from the interface for testing 43. In this case, the address data is output as data of 13 Bits when the page length in a memory block within the memory cell array 21 is for example, 8 Kbytes. Therefore, because address data can not be output once in one cycle (11 clocks), an address is output in two cycles (11 clocks×2).

As stated above, in the fifth embodiment, at the time of a test operation, a flag FLG which shows the presence or not of a defective bit as a comparison result of 8 bit data is output and address data which shows the location where this defective bit occurs is output as fail bit address data FBA. As a result, it is possible to know in which 8 bit data defective bits are included during a comparison process of 8×8 bit data and it is also possible to know where this defective bit occurs. As a result, it is possible to reduce costs of the tester 2 and also reduce the time required for testing.

### SIXTH EMBODIMENT

In the sixth embodiment, an example in which the number of test pins of a NAND type flash memory chip are reduced, is explained. In addition, an example in which the time required for a test and the time required for outputting a test result of a memory block which has many defective bits is reduced is also explained.

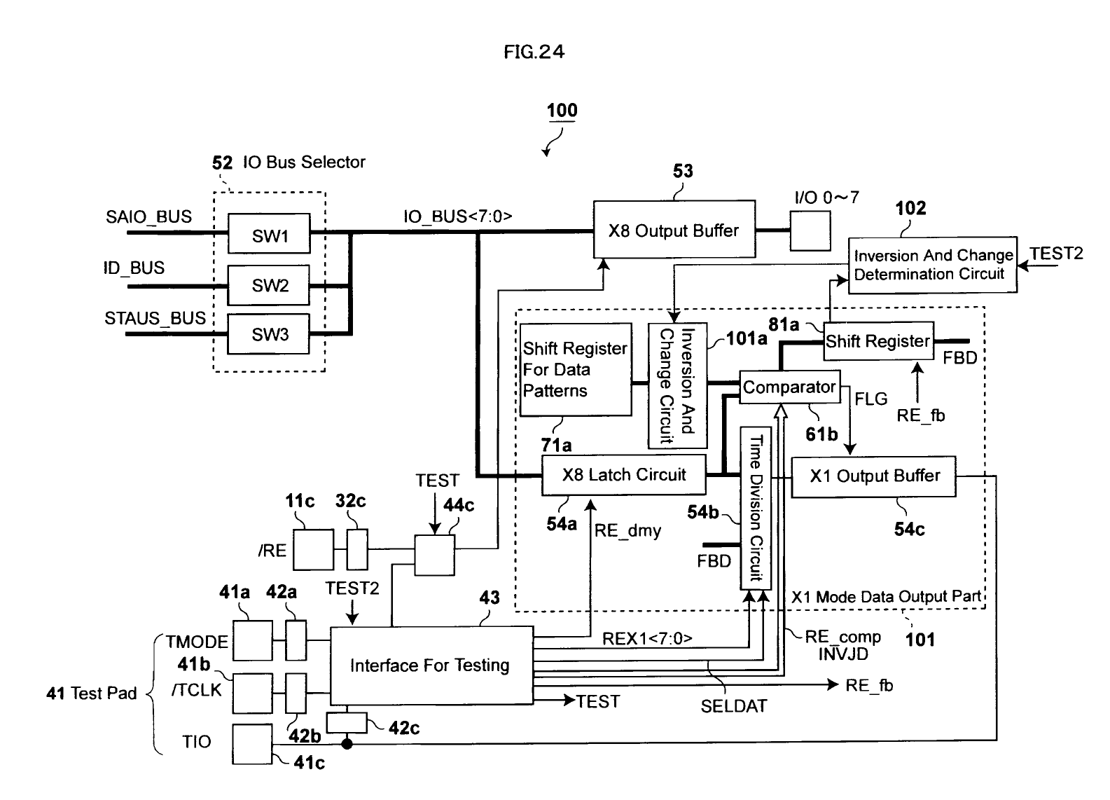

FIG. 24 is a diagram which shows a circuit structure of a data input/output part 100 in the NAND type flash memory chip 10 related to the sixth embodiment. In the data input/output part 100 shown in FIG. 24, the structural elements which are the same as in the data input/output part 50 shown in FIG. 10, the data input/output part 60 shown in FIG. 11, the data input/output part 70 shown in FIG. 14 and the data input/output part 80 shown in FIG. 16, have the same symbols and this an explanation of these structural elements will be omitted.

In the data input/output part 100 in the NAND type flash memory chip 10 related to the sixth embodiment, it is assumed that almost all the bits in a page are determined in advance to be defective bits similar to defective ROW in the memory cell array 21. In this case, by inverting and reading the data within this page, it is possible to reduce the output time of a test result in the case where there are many defective bits, reduce the time required for a test and also output details of the defective bits.

The data input/output part 100 includes an inversion and change determination circuit 102 which has a function to invert read data. The inversion and change determination circuit 102 determines whether an inversion and change of read data is required based on the number of defective bits included in the data read from a certain page in the memory cell array 21. Furthermore, an X1 mode data output part 101 includes an inversion and change circuit 101a. The inversion and change circuit 101a is activated in the case where it is determined in the inversion and change determination circuit 102 that an inversion and change are required and inverts and changes data patterns read from the shift register for data patterns 71a.

The inversion and change determination circuit 102 determines that it is necessary to invert and change read data in the case where defective bits (FLG=1) which are included in flags FLG which show comparison results for 8×8 bit data stored in the shift register 81a are a predetermined number, (for example, more than half of the total) and activates the inversion and change circuit 101a.

In the sixth embodiment, a test mode signal TEST 2 is input from the tester 2 as a test mode for initiating the inversion and change determination circuit 102. In addition, when the test mode signal TEST 2 is input, a control signal INVJD is input to the comparator 61b from the interface for testing 43. This control signal INVJD is a signal which sets a column address range when the comparator 61b reads data from a page within the memory cell array 21. A column address range is specified, for example, as a column address a number of columns from the head column in a page and a column address a number of columns form the last column. That is, by reading data from a plurality of column addresses with are separated within a page rather than reading data from adjacent column address it is possible to increase accuracy when the number of defective bits included in a page is determined. Furthermore, the column address range in which data is read is not limited and can be appropriately changed according to page capacity for example within a memory cell array.

When the control signal INVJD (“High”) is input from the interface for testing 43, 8 bit data is sequentially read from a plurality of columns within the above stated page and the comparator 61b compares this data with a data pattern read from the shift register for data patterns 71a. The comparator 61b stores a comparison result of this 8 bit data in the shift register 81a. At this time, the inversion and change circuit 101a is not activated and the data pattern which is read from the shift register for data patterns 71a is input to the comparator 61b without being inverted.

The inversion and change determination circuit 102 determines whether it is necessary to invert and change read data depending on whether the number of defective bits which are included in flags FLG which show comparison results for 8×8 bit data of separated plurality of column addresses stored in the shift register 81a are a predetermined number, (for example, more than half of the total).

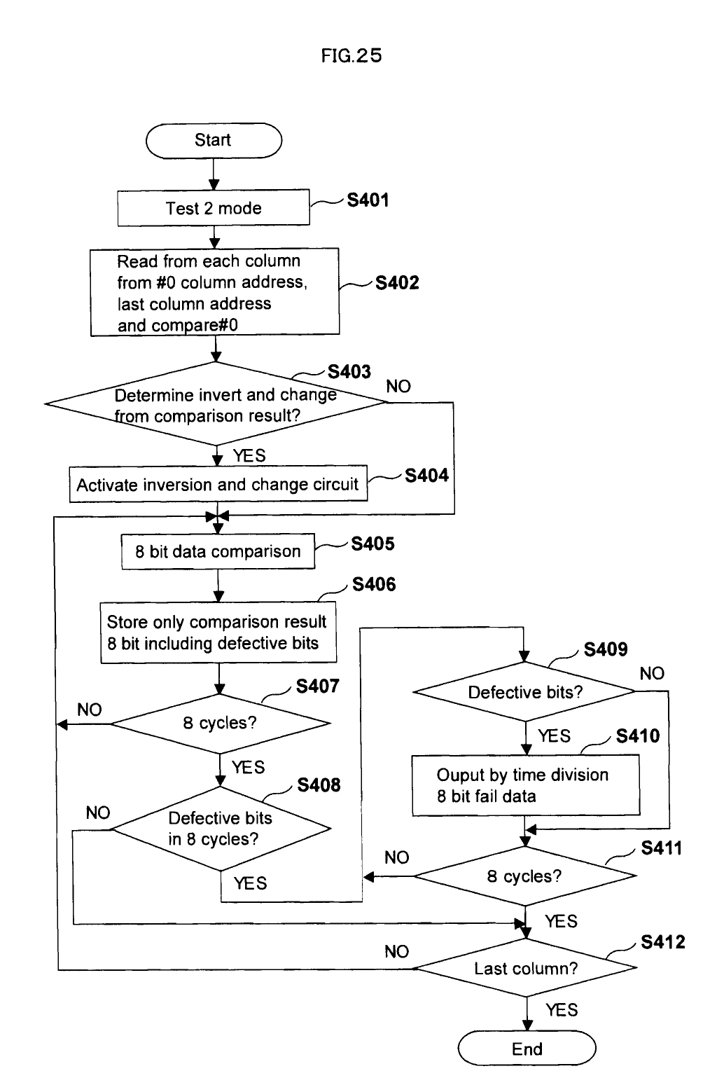

Next, a test operation within the NAND type flash memory chip 10 related to the sixth embodiment will be explained while referring to the flowchart in FIG. 25.

In FIG. 25, a test operation is begun and when a test mode signal TEST 2 is input to the interface for testing 43 of the data input/output part 100 within the NAND type flash memory chip 10 from the tester 2 (step S401), the interface for testing 43 inputs the control signal INVJD (“High”) to the comparator 61b. In addition, the test mode signal TEST is input to the inversion and change determination circuit 102 and the inversion and change determination circuit 102 is initiated.

When the control signal INVJD (“High”) is input 8 bit data of each column address from the column address #0 and last column address of a page within the memory cell array 21 is sequentially read and the comparator 61b compares this data with a data pattern read from the shift register for data patterns 71a (step S402). The comparator 61b stores flags FLG (8 bit) which show comparison results for 8×8 bit data in the shift register 81a.

Next, the inversion and change determination circuit 102 determines whether a page is ROW defective or not depending on whether flags FLG (FLG=1) which include defective bits among flags FLG of 8 bits are more than half the total based on flags FLG (8 bits) which show comparison results for 8×8 bit data stored in the shift register 81a (step S403). If the inversion and change determination circuit 102 determines that the page is ROW defective (step S403: YES), the process shifts to step S404 and activates the inversion and change circuit 101a. In addition, if the inversion and change determination circuit 102 determines that the page is not ROW defective (step S403: NO), the process shifts to step S405.

Below, operations after step S405 in the case where the inversion and change circuit 101a is initiated in step S404 will be explained.

In step S405, the 8 bit data which is to be compared is read from the page which is determined to be ROW defective in the memory cell array 21 and the comparator 61b reads an 8 bit data pattern from the shift register for data patterns 71 a compares this with the data from the ROW defective page. In this case, the data which is read from the shift register for data patterns 71a is inverted and changed by the inversion and change circuit 101a. That is, “0” of a data pattern is inverted to “1” and “1” is inverted to “0”. Therefore, in a comparison result of 8 bit data, matching bits (below referred to as normal bits) become “1” and non-matching bits (below referred to as defective bits) become “0”. In addition, the flags FLG which show comparison results of 8 bit data which includes defective bit become “0” and the flags FLG which show comparison results of 8 bit data which do not include defective bit become “1”.

Next, the comparator 61b outputs comparison results of 8 bit data which show the above comparison results to the shift register 81a and also output flags FLG which show these comparison results to the X1 output buffer 54c. The shift register 81a correlates only the 8 bit data which includes normal bits among the comparison results of 8 bit data which are input from the comparator 61b, with the addresses #0 to #7 and stores them (step S406).

Next, the comparator 61b and the shift register 81a repeat the processes in the above stated steps S405 and S406 for 8 cycles (step S407). By the operations in these 8 cycles the shift register 81a correlates only the 8 bit data which includes normal bits among the 8 bit data which is input from the comparator 61b, with the column addresses #0 to #7 and sequentially stores them.

Next, the shift register 81a determines whether there are defective bits in the comparison process of 8×8 bit data performed for 8 cycles (step S408). In this case, “1” shows a normal bit with the 8 bit data and if this “1” is included (step S408: YES) the process shifts to step S409.

In step S409 the shift register 81a further confirms whether there are defective bits in each 8 bit data stored in the column addresses #0 to #7 (step S408). In this case, “1” shows a normal bit with the 8 bit data and if this “1” is included (step S409: YES) the process shifts to step S410.

In step S410, the shift register 81a outputs by time division 8 bit data which includes defective bits as fail bit data FBD. Then, the shift register 81a repeats this output process by time division of the fail bit data FBD in the above stated step S410 for 8 cycles (step S411). In this case, a defective bit is set as “0” and a normal bit is set as “1” for each fail bit data FBD over the 8 cycles and output as a data code with the above stated 11 bit structure. In this data code the above stated Dummy Bit is set at “1”. When this Dummy Bit is set at “1” indicates that this is an output of fail bit data FBD.

Next, the comparator 61b confirms whether the data comparison process has been performed up to the last column with the same page (step S412). If the process has not been performed up to the last column (step S412: NO), the process returns to step S405 and the processes in steps S405 to step S411 are repeated. In addition, if the comparison process has been performed up to the last column (step S412: YES), then the test operation is complete.

In addition, operations after step S405 in the case where the inversion and change circuit 101a is not initiated in step S404 will be explained.

In step S405, the 8 bit data which is to be compared is read from a page within the memory cell array 21 and the comparator 61b reads an 8 bit data pattern from the shift register for data patterns 71a and compares this with the data to be compared. Then the comparator 61b outputs comparison results of the 8 bit data to the shift register 81a and also outputs flags FLG (1 bit data) which show the comparison results of this 8 bit data to the X1 output buffer 54c. In this case, the data pattern which is read from the shift register for data patterns 71a is not inverted. Therefore, in the comparison results of the 8 bit data, a normal bit becomes “0” and a defective bit becomes “1”. In addition, a flag FLG becomes “1” when it includes a defective bit and “0” when it does not include a defective bit.

Next, the shift register 81a correlates only 8 bit data which includes a defective bit among the 8 bit data which is input from the comparator 61b, with the column addresses #0 to #7 and stores them (step S406). Then, the comparator 61b and the shift register 81a repeat the processes in the above stated steps S405 and S406 for 8 cycles (step S407). By the operations in these 8 cycles the shift register 81a correlated only the 8 bit data which includes a defective bit among the 8 bit data which is input form the comparator 61b, with the column addresses #0 to #7 and sequentially stores them. In addition, the comparator 61b sequentially outputs flags FLG which show comparison results of 8×8 bit data to the X1 output buffer 54c.

Next, the shift register 81a determines whether there are defective bits in the comparison process of 8×8 bit data over 8 cycles (step S408). If there are no defective bits (step S408: NO), the process shifts to step S412. In addition, if there are defective bits (step S408: YES), the process shifts to step S409.

In step S409, the shift register 81a further confirms whether there are defective bits in each stored 8 bit data. If there are no defective bits (step S409: NO), the process shifts to step S411. In addition, if there are defective bits (step S409: YES), the process shifts to step S410.

In step S410 the shift register 81a outputs by time division 8 bit data which includes defective bits as fail bit data FBD. Then, the shift register 81a repeats for 8 cycles the output process by time division of the fail bit data FBD in the above stated step S410 (step S411).

Next, the comparator 61b confirms whether the data comparison process has been performed up to the last column within the same page (step S412). If the comparison process has not been performed up to the last column (step S412: NO), the process returns to step S405 and the processes in steps S405 to S411 are repeated. In addition, if the comparison process has been performed up to the last column (step S412: YES), then the test operation is complete.

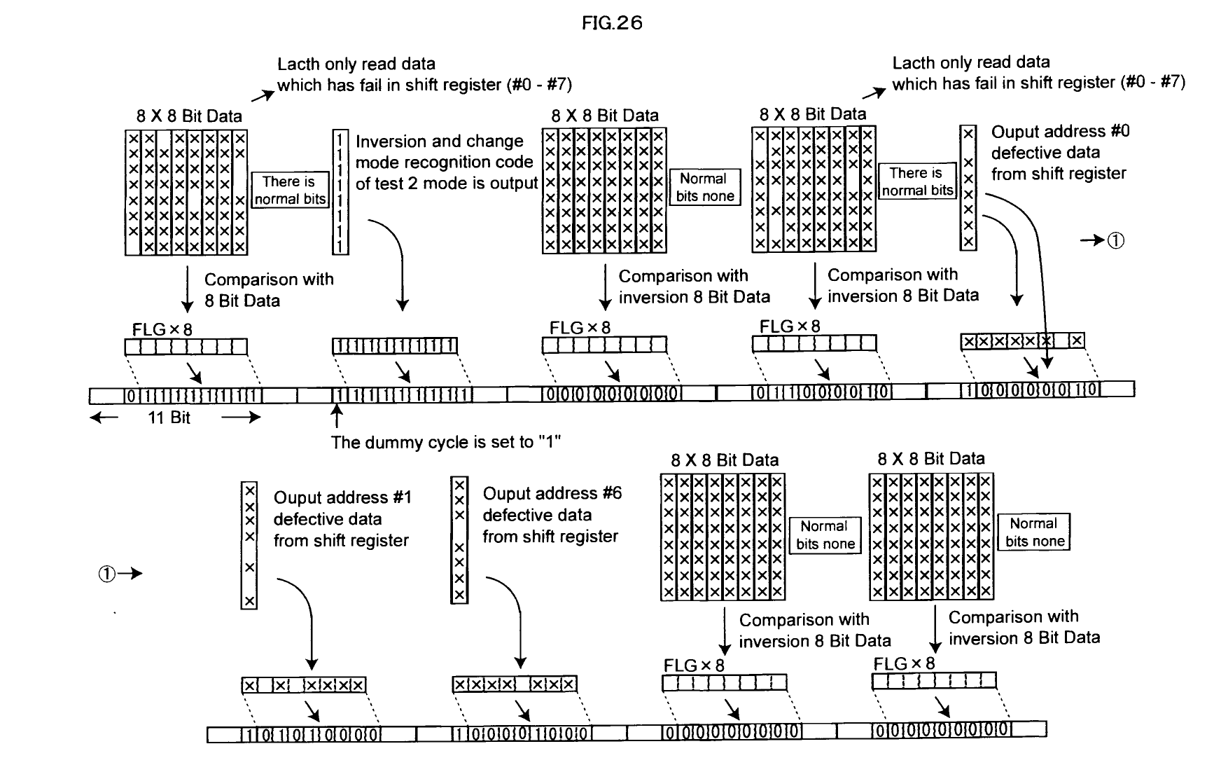

Next, a specific example of the comparison operation of 8 bit data and the output of fail bit data FBD by the above stated test operation will be explained by referring to FIG. 26.

In the comparison process of the first 8×8 bit data in FIG. 26, data within a page is compared which is determined in advance as ROW defective. 8 bit data in each of a number of columns from the column address #0 and last column address with this page, is sequentially read and the case is shown where all the flag FLG which show a result of a comparison with a data pattern which is read from the shift register for data patterns 71a are “1”. In this case, the flags FLG which show comparison results of 8×8 bit data (“1”×8) are output as a data code with an 11 bit structure and a Dummy Bit is set at “0”

Next, a test mode signal TEST 2 is input to the interface for testing 43 and the inversion and change determination circuit 102 from a control circuit and the inversion and change determination circuit 102 is initiated. In the inversion and change determination circuit 102 this page is determined as ROW defective based on a comparison result of the above stated first 8×8 bit data and the inversion and change circuit 101a is activated.

Next, the data which is to be compared is read from a page determined to be ROW defective and the comparator 61b reads a data pattern from the shift register for data patterns 71a and compares them. In this case, because the data which is read from the shift register for data patterns 71a is inverted and changed by the inversion and change circuit 101a, the comparator 61b reads the data as inverted and changed data. Therefore, in the comparison result of 8 bit data, ALL=0 and a flag FLG=0.

In this case the comparator 61b sequentially outputs flags FLG which show comparison results of 8×8 bit data to the X1 output buffer 54c and the shift register 81a according to a RE_comp clock signal input from the interface for testing 43. In addition, the shift register 81a correlates the addresses #0 to #7 and the flags FLG which are comparison results of 8×8 bit data input from the comparator 61b are latched. Then, the shift register 81a outputs by time division fail bit data FBD of the stored 8×8 bit data according to a clock cycle of fail bit read signal RE_fb input from the interface for testing 43.

In FIG. 26, when a data code which includes fail bit data FBD which shows a comparison result of a first 8×8 bit data is output, “1” is set to the Dummy Bit which includes this data code. By setting “1” to this Dummy Bit, a Dummy Bit Cycle is shown.

The comparison result of 8×8 bit data of a page which is determined as ROW defective is output as an a data code with an 11 bit structure which includes fail bit data FBD with an 8 bit structure, as above. As a result, it is possible to reduce a comparison result output cycle.

In FIG. 26, the comparison process of the next 8×8 bit data is shown as not having any defective bits, however, because it is a result which is compared with an inverted data pattern, actually all the bits are defective bits. In this case, the comparator 61b sequentially outputs flags FLG which show comparison results of 8×8 bit data to the X1 output buffer 54c according to a RE_comp clock signal input from the interface for testing 43. In this case, the flags FLG which show comparison results of 8×8 bit data are all output as “0”. Actually, because it is a comparison with an inverted 8 bit data pattern, it is necessary to interpret it as a comparison result which includes all the defective bits.

The case where there are defective bits in the comparison process of the next 8×8 bit data is shown in FIG. 26. In this case, the comparator 61b sequentially outputs flags FLG (1 bit data) which show comparison results of 8×8 bit data to the X1 output buffer 54c according to a RE_comp clock signal which is input from the interface for testing 43. The flags FLG=1 when there is at least one bit match among the 8 bits as stated above. In addition, the shift register 81a correlates the addresses #0 to #7 and only 8 bit data which has defective bits from among the comparison results of 8×8 bit data input from the comparator 61b are latched.

However, in this case also, because it is a comparison with an inverted 8 bit data pattern, the “0” in the diagram is a defective bit and “1” is a normal bit. In this case, only 3×8 bit data which includes normal bits among the 8×8 bit data is latched with addresses #0, #1 and #6 in the shift register 81a. Then, the shift register 81a outputs by time division the fail bit data FBD for each stored 8 bit data according to a clock cycle of a fail bit read signal RE_comp which is input from the interface for testing 43.

In FIG. 26, when a data code with an 11 bit structure which includes 8 bit data flags FLG and 8 bit fail bit data FBD is output, an example is shown which sets data which shows whether a flag FLG or fail bit data FBD is output to the Dummy Bit. For example, when a flag FLG is output “0” is set to the Dummy Bit and when fail bit data FBD is output “1” is set to the Dummy Bit.

In FIG. 26, after a flag FLG which includes normal bits in the above stated 8×8 bit data is output, fail bit data FBD with an 8 bit structure which includes defective bits which are correlated with the location of a normal bit (addresses #0 to #7) are sequentially output in 8 bit data units from the shift register 81a.

Specifically, as is shown in FIG. 26, 8 bit data on the left of the 8×8 bit data in the diagram, that is, one normal bit is included in the 8 bit data stored in address #0 within the shift register 81a. 8 bit fail bit data FBD which includes data “1” (defective bit is “0”) which shows the location of this normal bit is output as a data code with an 11 bit structure. Then, the second 8 bit data from the left among the 8×8 bit data in the diagram, that is, two normal bits are included in the 8 bit data stored in address #1 within the shift register 81a. 8 bit fail bit data FBD which includes data “1” (defective bit is “0”) which shows the location of this normal bit is output as a data code with an 11 bit structure. Furthermore, X in the diagram indicates a normal bit.

Next, the seventh 8 bit data from the left among the 8×8 bit data in the diagram, that is, one normal bit is included in the 8 bit data stored in address #6 within the shift register 81a. 8 bit fail bit data FBD which includes data “1” (defective bit is “0”) which shows the location of this normal bit is output as a data code with an 11 bit structure. When these fail bit data FBD are output, a Dummy Bit is set at “1”.

The remaining output processes by time division of flags FLG which show comparison results (all are defective bits) of 8×8 bit data in the diagram, are performed in the same way as described above.

In the sixth embodiment, at the time of a test operation, it is possible to output in a short time a comparison result of data within a page which is determined in advance to have many defective bits. As a result, it is possible to reduce the test time required for outputting data. Furthermore, in the sixth embodiment, a comparison process of data was carried out assuming that “1” was a normal bit and “0” was a defective bit, however, even in the case where a normal bit is “0” and a defective bit is “1” the above stated data comparison process can be applied.

Furthermore, in the sixth embodiment, an example was shown where the shift register 81a outputs by time division fail bit data FBD of the stored 8×8 bit data according to a clock cycle of a fail bit read signal RE_fb which is input form the interface for testing 43. The shift register 81a stores a flag which shows the location where a defective bit occurs within the 8 bit data and detailed fail bit data FBD which shows the location where a defective bit occurs may also be output according to a fail bit read signal RE_fb. In addition, the shift register 81a stores only address data which shows the location where a defective bit occurs within the 8 bit data may also output only this stored address data as fail bit address data FBA according to a fail bit read signal RE_fb.

What is claimed is:

1. A semiconductor memory device comprising:
a memory cell array including a plurality of memory cells;
a first interface part having a predetermined number of pins;
a second interface part having a smaller number of said pins than said first interface part;
a data pattern latch part which stores an externally input or preliminarily set data pattern;
a comparison part which compares said data pattern input from said data pattern latch part with data which is read from said memory cell array; and
a comparison result output part arranged in said second interface part, and which outputs a comparison result of said comparison part.

2. The semiconductor memory device according to claim 1, wherein said comparison part sequentially compares data read from said memory cell array with a data pattern which is stored in said data pattern latch part according to a clock signal which is externally input, and said comparison result output part outputs by time division said comparison result which is sequentially input from said comparison part.

3. The semiconductor memory device according to claim 1, wherein said data pattern latch part stores a plurality of different data patterns and said plurality of different data patterns are sequentially input to said comparison part at a timing synchronized with an externally input clock signal, and said comparison part compares data patterns which are sequentially input from said data pattern latch part, with data which is sequentially read from said memory cell array.

4. The semiconductor memory device according to claim 1 further comprising:
a comparison result storage part which stores a comparison result output from said comparison part;
wherein
said comparison part compares said data pattern with said data and outputs mismatch data as a comparison result when said data pattern and said data do not match, said comparison result storage part stores said mismatch data output from said comparison part, and said comparison result output part outputs by time division said mismatch data which is stored in said comparison result storage part.

5. The semiconductor memory device according to claim 1 further comprising:
a data pattern shift part which stores a plurality of different data patterns having the same number of bits and sequentially inputs said plurality of different data patterns to said comparison part at a timing synchronized with an externally input clock signal;
wherein
said comparison part compares said plurality of different data patterns sequentially input from said data pattern shift part, with data which is sequentially read from said memory cell array.

6. The semiconductor memory device according to claim 1 further comprising a comparison result retention part which retains a plurality of comparison results which are sequentially output from said comparison part within a fixed time period, and outputs said retained plurality of comparison results by time division according to an externally input read signal.

7. The semiconductor memory device according to claim 6, wherein said comparison result retention part determines whether said retained plurality of comparison results includes defects and in the case where said retained plurality of comparison results includes said defects, said comparison result retention part outputs by time division defect data which shows the location of said defects according to said read signal.

8. The semiconductor memory device according to claim 7, wherein said comparison result retention part outputs by time division defect data which shows the location where said defects occur to said comparison result output part according to said read signal in the case where a plurality of said defects are included in said plurality of comparison results.

9. The semiconductor memory device according to claim 6, wherein said comparison result retention part only retains a comparison result which includes a defect from among said plurality of comparison results output from said comparison part and outputs by time division defect data which shows the location of said defects according to said read signal.

10. The semiconductor memory device according to claim 6, wherein said comparison result retention part only retains address data of defects among said plurality of comparison results output from said comparison part and outputs by time division said defect data which includes said address data according to said read signal.

11. The semiconductor memory device according to claim 1, further comprising;
an inversion and change determination part which determines the necessity of inverting and changing said data pattern input from said data pattern latch part based on the number of defective bits included in said plurality of data read from said memory cell array;
an inversion and change part which inverts sand changes said data pattern input from said data pattern latch when said inversion and change determination part determines an inversion and change is necessary;
wherein
said comparison part compares said data pattern sequentially input from said data pattern latch with said plurality of data sequentially read from said memory cell array.

12. The semiconductor memory device according to claim 11, wherein said comparison part sets an address range of a data read destination within said memory cell array by an externally input control signal, and said inversion and change determination part determines the necessity of inverting and changing said data pattern input from said data pattern latch part based on the number of defective bits included in said plurality of data read from said address range within said memory cell array.

13. The semiconductor memory device according to claim 12, wherein said comparison part sets a plurality of addresses which are separated within said address range as a data read destination by said externally input control signal, and said inversion and change determination part determines the necessity of inverting and changing said data pattern input from said data pattern latch part based on the number of defective bits included in said plurality of data read from said plurality of addresses separated within said address range within said memory cell array.

14. The semiconductor memory device according to claim 11, wherein said inversion and change determination part initiates said inversion and change part when determines said inversion and change of said data pattern is necessary.

15. The semiconductor memory device according to claim 11, wherein said comparison part compares said inputted data pattern inverted and changed by said inversion and change part with data read from said memory cell array.

16. The semiconductor memory device according to claim 11 further comprising a comparison result retention part which retains a plurality of comparison results which are sequentially output from said comparison part within a fixed time period, and outputs said retained plurality of comparison results by time division according to an externally input read signal.

17. The semiconductor memory device according to claim 11, wherein said comparison result retention part determines whether said retained plurality of comparison results includes defects and in the case where said retained plurality of comparison results includes said defects, said comparison result retention part outputs by time division defect data which shows the location of said defects according to said read signal.

18. The semiconductor memory device according to claim 15, wherein said comparison result retention part outputs by time division defect data which shows the each location where said defects occur according to said read signal in the case where a plurality of said defects are included in said plurality of comparison results.

19. The semiconductor memory device according to claim 11, wherein said comparison result retention part only retains a comparison result which includes a defect among said plurality of comparison results output from said comparison part and outputs by time division defect data which shows the location of said defects occur according to said read signal.

20. The semiconductor memory device according to claim 11, wherein said comparison result retention part only retains address data of defects among said plurality of comparison results output from said comparison part and outputs by time division said defect data which includes said address data according to said read signal.
